(19) United States
(12) Patent Application Publication
(10) Pub. No.: US 2026/0223369 A1
(43) Pub. Date: Jul. 30, 2026

(54) SEMICONDUCTOR MEMORY DEVICE AND METHOD OF MANUFACTURING THE SEMICONDUCTOR MEMORY DEVICE

(71) Applicant: SK hynix Inc., Icheon-si Gyeonggi-do (KR)

(72) Inventor: Kang Sik CHOI, Icheon-si Gyeonggi-do (KR)

(73) Assignee: SK hynix Inc., Icheon-si Gyeonggi-do (KR)

(21) Appl. No.: 19/574,057

(22) Filed: Mar. 20, 2026

Related U.S. Application Data
(63) Continuation-in-part of application No. 17/406,953, filed on Aug. 19, 2021.

(30) Foreign Application Priority Data
Mar. 4, 2021 (KR) 10-2021-0028909

(51) Int. Cl. H10B 43/27; G11C 16/04; H10B 43/10; H10B 43/35; H10D 80/30; H10W 90/00

(52) U.S. Cl. CPC H10B 43/27; G11C 16/0483; H10B 43/10; H10B 43/35; H10D 80/30; H10W 90/792

(57) ABSTRACT

Provided herein is a semiconductor memory device and a method of manufacturing the semiconductor memory device. The semiconductor memory device include a stacked body including conductive layers and insulating layers that are alternately stacked; gate patterns disposed over the stacked body; a separation insulating pattern disposed over the stacked body, wherein the separation insulating pattern includes a first portion between adjacent gate patterns and a second portion between the gate patterns and the stacked body; a first channel layer extending through the stacked body; a core insulating layer disposed in the first channel layer; a memory layer disposed between the stacked body and the first channel layer; a second channel layer extending through the gate pattern and the second portion, wherein the second channel layer is disposed over the core insulating layer to contact the first channel layer and has a solid structure; and a gate insulating layer disposed between the second channel layer and the gate pattern.

### CROSS-REFERENCE TO RELATED APPLICATION

The present application is a continuation-in-part application of U.S. patent application Ser. No. 17/406,953, filed on Aug. 19, 2021, which claims priority under 35 U.S.C. § 119(a) to Korean patent application number 10-2021-0028909 filed on Mar. 4, 2021, in the Korean Intellectual Property Office, the entire contents of which applications are incorporated by reference herein.

### BACKGROUND

### 1. Technical Field

Various embodiments of the present disclosure relate to a semiconductor memory device and a method of manufacturing the semiconductor memory device, and more particularly to a three-dimensional (3D) semiconductor memory device and a method of manufacturing the 3D semiconductor memory device.

2. Related Art

In order to improve the degree of integration of a semiconductor memory device, a three-dimensional (3D) semiconductor memory device has been proposed. The 3D semiconductor memory device may include memory cells arranged in three dimensions. The memory cells of the 3D semiconductor memory device may be stacked in a longitudinal direction of a channel structure. The channel structure may be coupled to bit lines and source lines under the control of select transistors.

### SUMMARY

An embodiment of the present disclosure may provide for a semiconductor memory device. The semiconductor memory device may include a stacked body including conductive layers and insulating layers that are alternately stacked; gate patterns disposed over the stacked body; a separation insulating pattern disposed over the stacked body, wherein the separation insulating pattern includes a first portion between adjacent gate patterns and a second portion between the gate patterns and the stacked body; a first channel layer extending through the stacked body; a core insulating layer disposed in the first channel layer; a memory layer disposed between the stacked body and the first channel layer; a second channel layer extending through the gate pattern and the second portion, wherein the second channel layer is disposed over the core insulating layer to contact the first channel layer and has a solid structure; and a gate insulating layer disposed between the second channel layer and the gate pattern.

An embodiment of the present disclosure may provide for a semiconductor memory device. The semiconductor memory device may include a stacked body including conductive layers and insulating layers that are alternately stacked; a separation insulating pattern disposed over the stacked body, wherein the separation insulating pattern is a single layer including a horizontal portion extending along an upper surface of the stacked body and a vertical portion protruding from the horizontal portion; a first gate pattern on the horizontal portion of the separation insulating pattern; a second gate pattern on the horizontal portion of the separation insulating pattern, wherein the first gate pattern and the second gate pattern are isolated from each other by the vertical portion; a first channel structure extending through the first gate pattern, the horizontal portion, and the stacked body; a second channel structure extending through the second gate pattern, the horizontal portion and the stacked body; and a slit structure extending through the horizontal portion and the stacked body.

### BRIEF DESCRIPTION OF THE DRAWINGS

FIG. 1 is a circuit diagram illustrating a memory cell array of a semiconductor memory device according to an embodiment of the present disclosure.

FIG. 2A is a perspective view schematically illustrating a partial area of a semiconductor memory device according to an embodiment of the present disclosure.

FIG. 2B is an enlarged sectional view of area A of FIG. 2A.

FIGS. 3A and 3B illustrate embodiments of a layout of a semiconductor memory device at a level at which drain select lines are arranged.

FIG. 4 is a sectional view of a semiconductor memory device taken along line I-I′ of FIG. 3A.

FIG. 5A is a sectional view of a semiconductor memory device according to an embodiment of the present disclosure.

FIG. 5B is an exploded perspective view of a partial area of the semiconductor memory device of FIG. 5A.

FIG. 6 is a sectional view of a semiconductor memory device according to an embodiment of the present disclosure.

FIG. 7 is a plan view illustrating a stacked body, a memory layer, and lower channel portions.

FIGS. 8A, 8B, and 8C are sectional views illustrating an embodiment of a method of manufacturing the stacked body, the memory layer, and the lower channel portions.

FIGS. 9 and 10 are respectively a plan view and a sectional view illustrating an embodiment of a method of manufacturing an upper stacked body and a first mask pattern.

FIGS. 11A, 11B, 11C, and 11D are sectional views illustrating embodiments of subsequent processes to be performed after the first mask pattern is formed.

FIG. 12 is a sectional view illustrating an embodiment of a subsequent process to be performed after an insulating layer is formed.

FIG. 13 is a plan view taken along line III-III′ of FIG. 12.

FIGS. 14 and 15 are respectively a plan view and a sectional view illustrating an embodiment of a method of manufacturing a separation insulating pattern.

FIG. 16 is a sectional view illustrating an embodiment of a method of manufacturing a conductive layer.

FIGS. 17A, 17B, and 17C are enlarged sectional views illustrating embodiments of subsequent processes for area C illustrated in FIG. 16.

FIG. 18 is a plan view taken along line IV-IV′ of FIG. 17C.

FIG. 19 is a plan view illustrating a first mask pattern, an upper insulating layer, a sidewall insulating layer, and a vertical source contact.

FIGS. 20A, 20B, 20C, 20D, and 20E are sectional views illustrating embodiments of a method of manufacturing the structure of FIG. 19.

FIGS. 21A, 21B, 21C, 21D, and 21E are sectional views illustrating embodiments of subsequent processes to be performed after the structure of FIG. 20E is formed.

FIGS. 22A and 22B are enlarged sectional views illustrating embodiments of subsequent processes for area C illustrated in FIG. 16.

FIGS. 23A, 23B, 23C, 23D, 23E, 23F, 23G, and 23H are sectional views illustrating embodiments of subsequent processes to be performed after the process of FIG. 11D.

FIG. 24 is a block diagram illustrating the configuration of a memory system according to an embodiment of the present disclosure.

FIG. 25 is a block diagram illustrating the configuration of a computing system according to an embodiment of the present disclosure.

FIG. 26 is a diagram illustrating the structure of a semiconductor device in accordance with an embodiment.

FIG. 27 is a diagram illustrating the structure of a semiconductor device in accordance with an embodiment.

FIG. 28 is a diagram illustrating the structure of a semiconductor device in accordance with an embodiment.

FIGS. 29A, 29B, and 29C are diagrams illustrating the structure of a semiconductor device in accordance with an embodiment.

FIGS. 30A, 30B, 30C, and 30D are diagrams illustrating the structure of a semiconductor device in accordance with an embodiment.

FIGS. 31A and 31B are diagrams illustrating the structure of a semiconductor device in accordance with an embodiment.

FIGS. 32A, 32B, 32C, and 32D are a diagram illustrating the structure of a semiconductor device in accordance with an embodiment. FIG. 32C is a cross-sectional view taken along line B-B′ of FIG. 32A. FIG. 32D is a modified example of FIG. 32C and is a cross-sectional view taken along line C-C′ of FIG. 32A.

FIGS. 33A and 33B are diagrams illustrating the structure of a semiconductor device in accordance with an embodiment.

FIGS. 34A and 34B are diagrams illustrating the structure of a semiconductor device in accordance with an embodiment.

### DETAILED DESCRIPTION

Specific structural and functional descriptions disclosed herein are merely illustrative for the purpose of describing embodiments according to the concept of the present disclosure. Embodiments according to the concept of the present disclosure can be implemented in various forms, and they should not be construed as being limited to the specific embodiments set forth herein.

It will be understood that, although the terms “first”, “second”, etc. may be used herein to describe various elements, these elements are not limited by these terms. These terms are used for distinguishing one element from another element and not to suggest a number or order of elements.

Various embodiments of the present disclosure are directed to a semiconductor memory device which has improved operational reliability, and a method of manufacturing the semiconductor memory device.

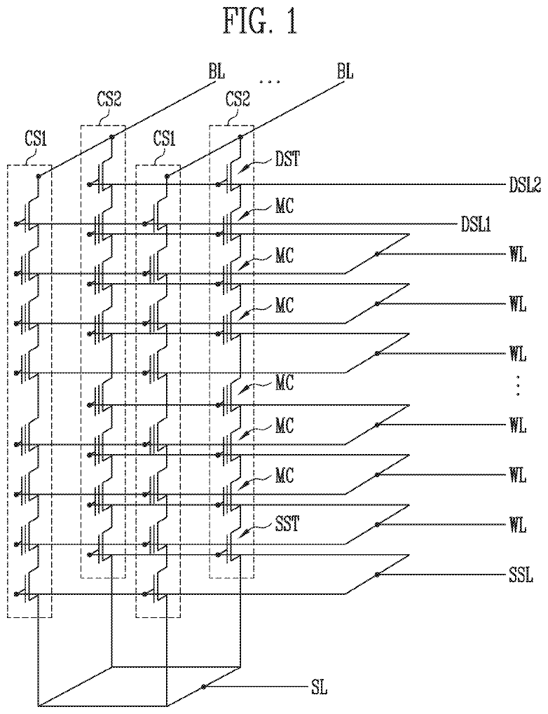

FIG. 1 is a circuit diagram illustrating a memory cell array of a semiconductor memory device according to an embodiment of the present disclosure.

Referring to FIG. 1, the memory cell array may include a plurality of memory cell strings CS1 and CS2 coupled to bit lines BL. The plurality of memory cell strings CS1 and CS2 may be coupled in common to a source line SL. In an embodiment, the plurality of memory cell strings CS1 and the plurality of memory cell strings CS2 may be coupled in common to the source line SL.

One pair of a first memory cell string CS1 and a second memory cell string CS2 may be coupled to each of the bit lines BL.

Each of the first memory cell strings CS1 and the second memory cell strings CS2 may include a source select transistor SST, a plurality of memory cells MC, and a drain select transistor DST which are arranged between the source line SL and a corresponding bit line BL.

The source select transistor SST may control electrical coupling between the plurality of memory cells MC and the source line SL. A single source select transistor SST may be arranged between the source line SL and the plurality of memory cells MC. Although not illustrated in the drawing, two or more series-coupled source select transistors may be arranged between the source line SL and the plurality of memory cells MC. The source select transistor SST may be coupled to a source select line SSL. The operation of the source select transistor SST may be controlled in response to a source gate signal applied to the source select line SSL.

The plurality of memory cells MC may be arranged in series between the source select transistor SST and the drain select transistor DST. The memory cells MC between the source select transistor SST and the drain select transistor DST may be coupled in series to each other. The memory cells MC may be coupled to word lines WL, respectively. The operation of the memory cells MC may be controlled in response to cell gate signals applied to the word lines WL.

The drain select transistor DST may control electrical coupling between the plurality of memory cells MC and the corresponding bit line BL. The drain select transistor DST may be coupled to a drain select line DSL1 or DSL2. The operation of the drain select transistor DST may be controlled in response to a drain gate signal applied to the drain select line DSL1 or DSL2.

The first memory cell strings CS1 may be coupled to the first drain select line DSL1. The second memory cell strings CS2 may be coupled to the second drain select line DSL2. Accordingly, either the first memory cell strings CS1 or the second memory cell strings CS2 may be selected by selecting one of the bit lines BL and selecting one of the first drain select line DSL1 and the second drain select line DSL2.

The first memory cell strings CS1 and the second memory cell strings CS2 may be coupled in common to respective word lines WL.

The first memory cell strings CS1 and the second memory cell strings CS2 may be coupled in common to the source select line SSL. Embodiments of the present disclosure are not limited thereto. Although not illustrated in the drawing, the memory cell array may include a first source select line and a second source select line which are separated from each other in an embodiment. The first source select line may be coupled to the first memory cell strings, and the second source select line may be coupled to the second memory cell strings.

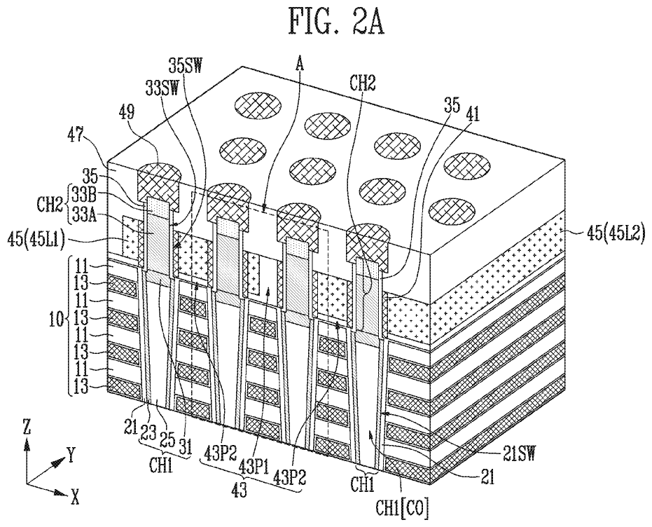

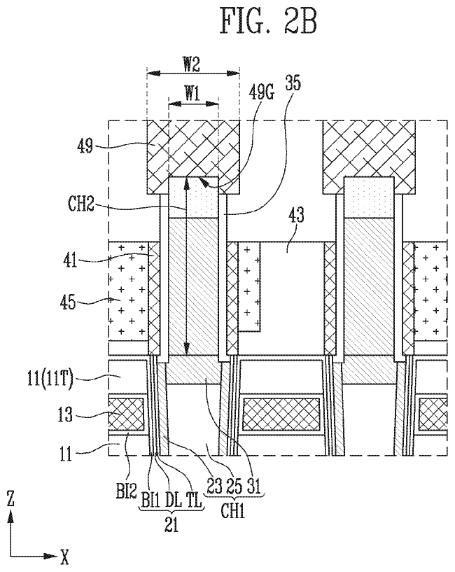

FIG. 2A is a perspective view schematically illustrating a partial area of a semiconductor memory device according to an embodiment of the present disclosure.

Referring to FIG. 2A, the semiconductor memory device may include a stacked body 10, channel structures, a memory layer 21,, gate insulating layers 35, first gate patterns 41, second gate patterns 45, and a separation insulating pattern 43. The channel structures may include lower channel portions CH1 and upper channel portions CH2.

The stacked body 10 may include conductive patterns 13 and interlayer insulating layers 11. FIG. 2A illustrates a portion of the stacked body 10. The conductive patterns 13 illustrated in FIG. 2A may be used as the word lines WL described above with reference to FIG. 1. Each of the interlayer insulating layers 11 and the conductive patterns 13 may have a planar shape extending in an X-Y plane. The interlayer insulating layers 11 and the conductive patterns 13 may be alternately stacked in a Z axis direction. The Z axis direction may be defined as a longitudinal direction of each of the lower channel portions CH1 and the upper channel portions CH2.

The lower channel portions CH1 may penetrate the stacked body 10. The memory layer 21 may be disposed between each of the lower channel portions CH1 and the stacked body 10. FIG. 2A illustrates a portion of each of the lower channel portions CH1 and a portion of the memory layer 21.

Each of the lower channel portions CH1 may include a channel layer 23, a core insulating layer 25, and a semiconductor pattern 31. The channel layer 23 may extend along an inner wall 21SW of the memory layer 21. The channel layer 23 may include a semiconductor material such as silicon. The core insulating layer 25 and the semiconductor pattern 31 may fill a central area CH1 [CO] of each of the lower channel portions CH1. The core insulating layer 25 may be enclosed by the channel layer 23. The semiconductor pattern 31 may be disposed between the core insulating layer 25 and a corresponding upper channel portion CH2. The semiconductor pattern 31 may include a semiconductor material such as silicon.

The upper channel portions CH2 may be disposed on the lower channel portions CH1, respectively. The channel structure of each memory cell string may include the lower channel portion CH1 and the upper channel portion CH2 coupled to each other.

The upper channel portions CH2 may be stably coupled to the lower channel portions CH1 by the semiconductor pattern 31. Each of the upper channel portions CH2 may include a semiconductor material such as silicon. Each of the upper channel portions CH2 may include a first area 33A and a second area 33B. The first area 33A may be formed of a substantially intrinsic semiconductor material. The second area 33B may be a doped area including conductive impurities. In an embodiment, the second area 33B may include n-type impurities.

The gate insulating layers 35 may enclose respective sidewalls 33SW of the upper channel portions CH2. Each of the gate insulating layers 35 may include semiconductor oxide. In an embodiment, each of the gate insulating layers 35 may include silicon oxide.

The first gate patterns 41 may enclose respective sidewalls 35SW of the gate insulating layers 35.

The second gate patterns 45 may include a first line-shaped gate pattern 45L1 and a second line-shaped gate pattern 45L2 which are isolated from each other by the separation insulating pattern 43. The first line-shaped gate pattern 45L1 and the second line-shaped gate pattern 45L2 may extend in parallel. In an embodiment, each of the first line-shaped gate pattern 45L1 and the second line-shaped gate pattern 45L2 may extend in a Y axis direction.

The first gate patterns 41 spaced apart from each other may be coupled to each other through the first line-shaped gate pattern 45L1 or the second line-shaped gate pattern 45L2. The first line-shaped gate pattern 45L1 and some of the first gate patterns 41 coupled to the first line-shaped gate pattern 45L1 may be used as the first drain select line DSL1, described above with reference to FIG. 1. The second line-shaped gate pattern 45L2 and others of the first gate patterns 41 coupled to the second line-shaped gate pattern 45L2 may be used as the second drain select line DSL2, described above with reference to FIG. 1.

The first gate patterns 41 may include a kind of conductive material different from that of the second gate patterns 45. In an embodiment, the first gate patterns 41 may include a conductive barrier layer formed of titanium, titanium nitride or the like. The second gate patterns 45 may include a metal layer formed of tungsten or the like.

The first gate patterns 41 may include the same kind of conductive material as the second gate patterns 45. In an embodiment, the first gate patterns 41 and the second gate patterns 45 may include refractory metal. The refractory metal may include titanium nitride, tantalum nitride, tungsten nitride, etc.

The separation insulating pattern 43 may include a vertical portion 43P1 and a horizontal portion 43P2. The vertical portion 43P1 of the separation insulating pattern 43 may be disposed between the first line-shaped gate pattern 45L1 and the second line-shaped gate pattern 45L2. The first line-shaped gate pattern 45L1 and the second line-shaped gate pattern 45L2 may be isolated from each other by the vertical portion 43P1 of the separation insulating pattern 43. The horizontal portion 43P2 of the separation insulating pattern 43 may extend from the vertical portion 43P1. The horizontal portion 43P2 of the separation insulating pattern 43 may extend into space between each of the first line-shaped gate pattern 45L1 and the second line-shaped gate pattern 45L2 and the stacked body 10. The horizontal portion 43P2 of the separation insulating pattern 43 may enclose the first gate patterns 41.

Each of the interlayer insulating layers 11 and the conductive patterns 13 may extend continuously in an X-Y plane so that it overlaps the first line-shaped gate pattern 45L1, the vertical portion 43P1 of the separation insulating pattern 43, and the second line-shaped gate pattern 45L2.

The semiconductor memory device may further include an upper insulating layer 47 and conductive contacts 49.

The upper insulating layer 47 may cover the separation insulating pattern 43 and the second gate patterns 45. The conductive contacts 49 may be respectively arranged on the upper channel portions CH2. The conductive contacts 49 may be isolated from each other by the upper insulating layer 47.

FIG. 2B is an enlarged sectional view of area A of FIG. 2A.

Referring to FIG. 2B, the memory layer 21 may include a tunnel insulating layer TL, a data storage layer DL, and a first blocking insulating layer BI1. The first blocking insulating layer BI1 may enclose the channel layer 23. The first blocking insulating layer BI1 may extend into space between an uppermost interlayer insulating layer 11T of the stacked body 10 illustrated in FIG. 2A and the separation insulating pattern 43. The data storage layer DL may be disposed between the first blocking insulating layer BI1 and the channel layer 23. The data storage layer DL may include a material that is capable of trapping charges. In an example, the data storage layer DL may include silicon nitride. The tunnel insulating layer TL may be disposed between the data storage layer DL and the channel layer 23. The tunnel insulating layer TL may include an insulating material enabling charge tunneling. In an embodiment, the tunnel insulating layer TL may include silicon oxide.

The semiconductor memory device may further include a second blocking insulating layer BI2. The second blocking insulating layer BI2 may be disposed between the first blocking insulating layer BI1 and the conductive pattern 13. The second blocking insulating layer BI2 may extend into space between each of the interlayer insulating layers 11 and the corresponding conductive pattern 13. The first blocking insulating layer BI1 and the second blocking insulating layer BI2 may each include an insulating material which blocks charges. The second blocking insulating layer BI2 may include an insulating material having permittivity higher than that of the first blocking insulating layer BI1. In an embodiment, the first blocking insulating layer BI1 may include silicon oxide, and the second blocking insulating layer BI2 may include metal oxide.

The first gate pattern 41 may be spaced apart from the channel layer 23 and the semiconductor pattern 31 of each lower channel portion CH1. In an embodiment, the gate insulating layer 35 may extend into space between the first gate pattern 41 and the channel layer 23 of the lower channel portion CH1 and space between the first gate pattern 41 and the semiconductor pattern 31 of the lower channel portion CH1. In this way, the first gate pattern 41 may be spaced apart from the channel layer 23 and the semiconductor pattern 31 of each lower channel portion CH1 by the gate insulating layer 35.

Each of the gate insulating layer 35 and the upper channel portion CH2 may protrude higher than each of the first gate pattern 41 and the second gate pattern 45 in a direction towards the conductive contacts 49. The upper channel portion CH2 may protrude higher than the gate insulating layer 35 in the direction towards the conductive contacts 49.

A width W2 of each conductive contact 49 may be formed to be greater than a width W1 of the upper channel portion CH2. In an embodiment, the conductive contact 49 may overlap the upper channel portion CH2, and may extend onto the gate insulating layer 35.

The conductive contact 49 may include a groove 49G. An upper portion of the upper channel portion CH2 may be inserted into the groove 49G. Through the conductive contact 49, the upper channel portion CH2 may be coupled to the bit line BL, described above with reference to FIG. 1.

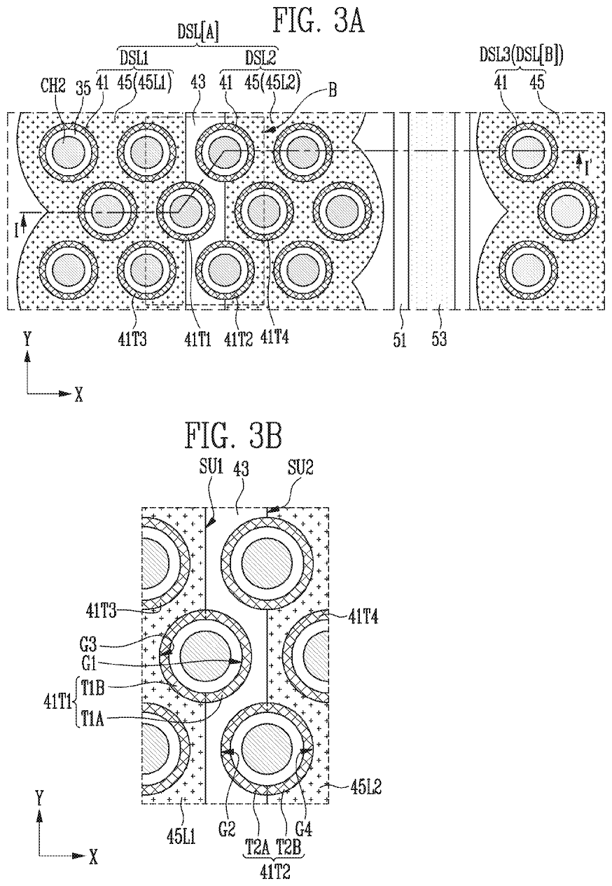

FIGS. 3A and 3B illustrate embodiments of a layout of a semiconductor memory device at a level at which drain select lines are arranged. FIG. 3A illustrates a layout of the semiconductor memory device in an area wider than that of the X-Y plane of FIG. 2A. FIG. 3B is an enlarged plan view illustrating area B illustrated in FIG. 3A. Hereinafter, repeated descriptions of overlapping components will be omitted.

Referring to FIG. 3A, the semiconductor memory device may include drain select lines DSL1, DSL2, and DSL3 which are divided into a first group DSL[A] and a second group DSL[B]. The first group DSL[A] and the second group DSL[B] may be disposed on both sides of a vertical source contact 53. In an embodiment, the first group DSL[A] may include the first drain select line DSL1 and the second drain select line DSL2, and the second group DSL[B] may include the third drain select line DSL3.

The vertical source contact 53 may include at least one of doped semiconductor, metal, metal silicide, and metal nitride.

The first group DSL[A] and the second group DSL[B] may be spaced apart from the vertical source contact 53. A sidewall of the vertical source contact 53 may be covered with a sidewall insulating layer 51.

Each of the first drain select line DSL1, the second drain select line DSL2, and the third drain select line DSL3 may include first gate patterns 41 spaced apart from each other and a second gate pattern 45 to couple the first gate patterns 41 to each other. The second gate pattern 45 of the first drain select line DSL1 may be defined as a first line-shaped gate pattern 45L1, and the second gate pattern 45 of the second drain select line DSL2 may be defined as a second line-shaped gate pattern 45L2.

The drain select lines of each group may be isolated from each other by the separation insulating pattern 43. In an embodiment, the separation insulating pattern 43 may be disposed between the first drain select line DSL1 and the second drain select line DSL2. The first line-shaped gate pattern 45L1 may be spaced apart from the second line-shaped gate pattern 45L2 through the separation insulating pattern 43.

Each of the first gate patterns 41 may be a tubular gate pattern. The gate insulating layer 35 and the upper channel portion CH2 may be inserted into a central area defined by the tubular gate pattern.

The first gate patterns 41 may be arranged in a plurality of rows. A row direction may be defined as the direction of extension of the second gate pattern 45. In an embodiment, the row direction may be a Y axis direction. Each second gate pattern 45 may couple the first gate patterns 41 arranged in two or more rows to each other. In an embodiment, each of the first line-shaped gate pattern 45L1 and the second line-shaped gate pattern 45L2 may couple the first gate patterns 41 arranged in four rows to each other.

The separation insulating pattern 43 may be disposed between two adjacent rows. A first row and a second row of the first gate patterns 41 may be defined as adjacent rows. The separation insulating pattern 43 may be disposed between the first row and the second row. The first row of the first gate patterns 41 may be defined as a row included in the first drain select line DSL1, and the second row of the first gate patterns 41 may be defined as a row included in the second drain select line DSL2.

The first gate patterns 41 may include a first tubular gate pattern 41T1 arranged in the first row, a second tubular gate pattern 41T2 arranged in the second row, a third tubular gate pattern 41T3 arranged in a third row, and a fourth tubular gate pattern 41T4 arranged in a fourth row. The third row of the first gate patterns 41 may be defined as a row included in the first drain select line DSL1, and the fourth row of the first gate patterns 41 may be defined as a row included in the second drain select line DSL2. The first row and the second row may be defined as rows disposed between the third row and the fourth row.

Referring to FIG. 3B, the separation insulating pattern 43 may include a first surface SU1 and a second surface SU2 which face in opposite directions. The separation insulating pattern 43 may include a first groove G1 formed in the first surface SU1 and a second groove G2 formed in the second surface SU2.

The first line-shaped gate pattern 45L1 may come into contact with the first surface SU1 of the separation insulating pattern 43. The first line-shaped gate pattern 45L1 may include a third groove G3 facing the first groove G1 of the separation insulating pattern 43. The second line-shaped gate pattern 45L2 may come into contact with the second surface SU2 of the separation insulating pattern 43. The second line-shaped gate pattern 45L2 may include a fourth groove G4 facing the second groove G2 of the separation insulating pattern 43.

The first tubular gate pattern 41T1 may extend along the surface of the first groove G1 and the surface of the third groove G3. The first tubular gate pattern 41T1 may be divided into a first portion T1A and a second portion T1B. The first portion T1A of the first tubular gate pattern 41T1 may be inserted into the first groove G1 of the separation insulating pattern 43, and may come into contact with the separation insulating pattern 43. The second portion T1B of the first tubular gate pattern 41T1 may extend from the first portion T1A, and may extend in a direction away from the separation insulating pattern 43. The second portion T1B of the first tubular gate pattern 41T1 may be inserted into the third groove G3 of the first line-shaped gate pattern 45L1, and may come into contact with the first line-shaped gate pattern 45L1.

The second tubular gate pattern 41T2 may extend along the surface of the second groove G2 and the surface of the fourth groove G4. The second tubular gate pattern 41T2 may be divided into a first portion T2A and a second portion T2B. The first portion T2A of the second tubular gate pattern 41T2 may be inserted into the second groove G2 of the separation insulating pattern 43, and may come into contact with the separation insulating pattern 43. The second portion T2B of the second tubular gate pattern 41T2 may be inserted into the fourth groove G4 of the second line-shaped gate pattern 45L2, and may come into contact with the second line-shaped gate pattern 45L2.

The first line-shaped gate pattern 45L1 may couple the first tubular gate pattern 41T1 to the third tubular gate pattern 41T3. The second line-shaped gate pattern 45L2 may couple the second tubular gate pattern 41T2 to the fourth tubular gate pattern 41T4.

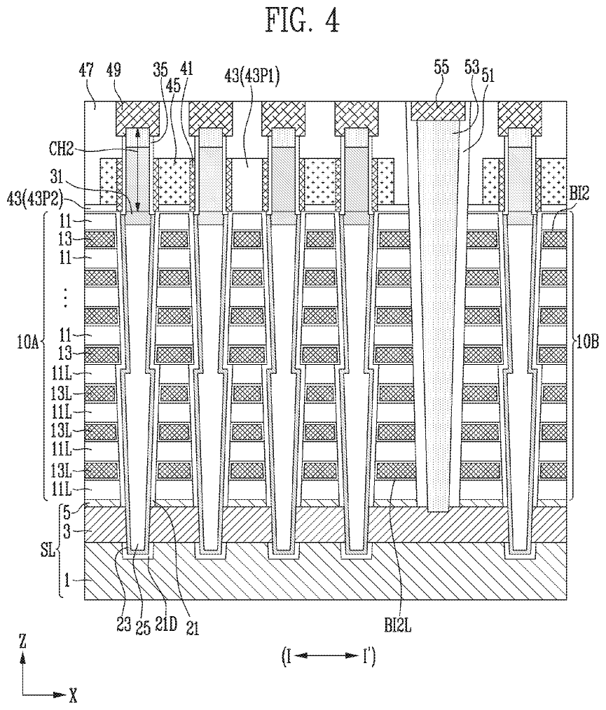

FIG. 4 is a sectional view of the semiconductor memory device taken along line I-I′ of FIG. 3A. Hereinafter, repeated descriptions of overlapping components will be omitted.

Referring to FIG. 4, the vertical source contact 53 may extend into space between stacked bodies 10A and 10B neighboring each other. The sidewall insulating layer 51 may extend into space between each of the stacked bodies 10A and 10B and the vertical source contact 53.

The semiconductor memory device may further include a source line SL. The stacked bodies 10A and 10B may be disposed on the source line SL.

Each of the stacked bodies 10A and 10B may further include lower interlayer insulating layers 11L and lower conductive patterns 13L as well as the interlayer insulating layers 11 and the conductive patterns 13, described above with reference to FIG. 2A. The lower interlayer insulating layers 11L and the lower conductive patterns 13L may be alternately stacked in the direction in which the interlayer insulating layers 11 and the conductive patterns 13 are alternately stacked.

The lower interlayer insulating layers 11L may be formed of the same insulating material as the interlayer insulating layers 11. The lower conductive patterns 13L may be formed of the same conductive material as the conductive patterns 13. Among the lower conductive patterns 13L, at least one layer adjacent to the source line SL may be used as the source select line SSL, described above with reference to FIG. 1.

The channel layer 23 and the memory layer 21 may extend to the source line SL to pass through the lower interlayer insulating layers 11L and the lower conductive patterns 13L. A lower blocking insulating layer BI2L may be disposed between each of the lower conductive patterns 13L and the memory layer 21. The lower blocking insulating layer BI2L may extend into space between each of the lower conductive patterns 13L and the corresponding lower interlayer insulating layers 11L. The lower blocking insulating layer BI2L may be formed of the same insulating material as the second blocking insulating layer BI2.

The source line SL may include a channel contact layer 3 that comes into contact with the channel layer 23. A structure for a contact between the channel contact layer 3 and the channel layer 23 may be variously implemented. In an embodiment, the channel contact layer 3 may enclose a portion of the sidewall of the channel layer 23, and may come into contact with the sidewall of the channel layer 23. The channel contact layer 3 may be formed of a semiconductor material including conductive impurities. In an embodiment, the channel contact layer 3 may include n-type doped silicon.

The source line SL may further include a first doped semiconductor layer 1 disposed under the channel contact layer 3. The first doped semiconductor layer 1 may be doped with impurities of at least one of n type and p type.

The channel layer 23 may extend to the inside of the first doped semiconductor layer 1. A dummy memory layer 21D may be further disposed between the channel layer 23 and the first doped semiconductor layer 1. The dummy memory layer 21D may be formed of the same materials as the memory layer 21. The dummy memory layer 21D and the memory layer 21 may be separated from each other by the channel contact layer 3. The channel layer 23 may extend into space between the dummy memory layer 21D and the core insulating layer 25.

The source line SL may further include a second doped semiconductor layer 5 disposed between each of the stacked bodies 10A and 10B and the channel contact layer 3. The second doped semiconductor layer 5 may include the same conductive impurities as the channel contact layer 3. Each of the memory layer 21, the channel layer 23, the core insulating layer 25, the sidewall insulating layer 51, and the vertical source contact 53 may pass through the second doped semiconductor layer 5.

The vertical source contact 53 may be coupled to the channel contact layer 3.

The sidewall insulating layer 51 and the vertical source contact 53 may protrude upwardly higher than the semiconductor pattern 31. In an embodiment, the sidewall insulating layer 51 and the vertical source contact 53 may pass through the horizontal portion 43P2 of the separation insulating pattern 43.

The sidewall insulating layer 51 and the vertical source contact 53 may protrude upwardly higher than each of the first gate pattern 41, the vertical portion 43P1 of the separation insulating pattern 43, and the second gate pattern 45. The upper insulating layer 47 and the sidewall insulating layer 51 may be interposed between the second gate pattern 45 and the vertical source contact 53.

The semiconductor memory device may further include an upper source contact 55 disposed on the vertical source contact 53. The upper source contact 55 may include the same conductive material as the conductive contacts 49. The upper insulating layer 47 and the sidewall insulating layer 51 may be interposed between the upper source contact 55 and the conductive contact 49 neighboring the upper source contact 55.

Although not illustrated in the drawing, the bit line BL, described above with reference to FIG. 1, may be disposed on the conductive contact 49, and may extend in a direction intersecting the second gate pattern 45.

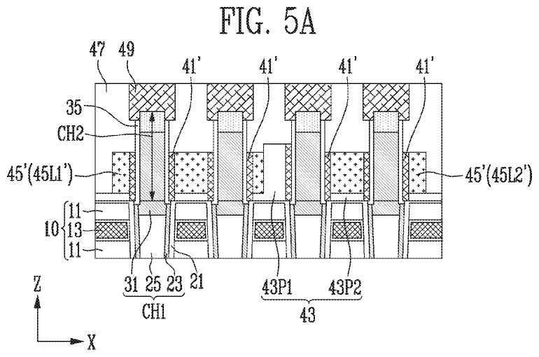

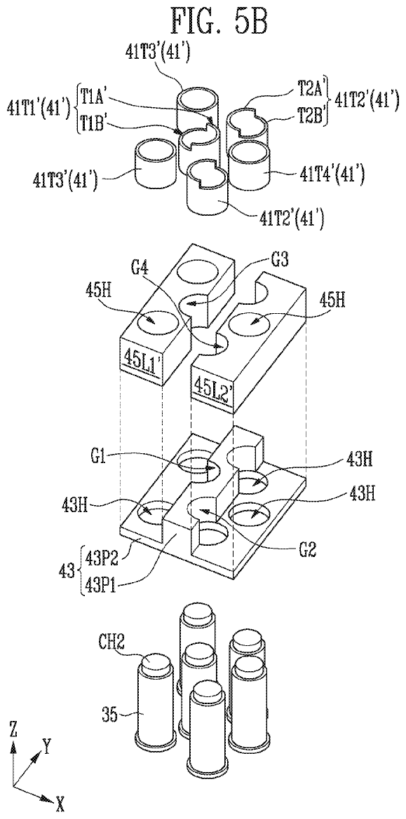

FIG. 5A is a sectional view of a semiconductor memory device according to an embodiment of the present disclosure. FIG. 5A illustrates a modification of first gate patterns 41′ and second gate patterns 45′. Hereinafter, repeated descriptions of overlapping components will be omitted.

Referring to FIG. 5A, the semiconductor memory device may include a stacked body 10, lower channel portions CH1, a memory layer 21, upper channel portions CH2, first gate patterns 41′, second gate patterns 45′, gate insulating layers 35, a separation insulating pattern 43, an upper insulating layer 47, and conductive contacts 49.

The stacked body 10 may include conductive patterns 13 and interlayer insulating layers 11. Each of the lower channel portions CH1 may include a channel layer 23, a core insulating layer 25, and a semiconductor pattern 31. The separation insulating pattern 43 may include a vertical portion 43P1 and a horizontal portion 43P2.

The vertical portion 43P1 of the separation insulating pattern 43 may protrude higher than the second gate patterns 45′ in a Z axis direction. In other words, the top surface of each of a first line-shaped gate pattern 45L1′ and a second line-shaped gate pattern 45L2′ of the second gate patterns 45′may be disposed at a level lower than that of the top surface of the vertical portion 43P1 of the separation insulating pattern 43.

Similar to the description made with reference to FIGS. 3A and 3B, the first gate patterns 41′ may include tubular gate patterns arranged in a plurality of rows. Some of the tubular gate patterns may be asymmetrically formed. Hereinafter, the tubular gate patterns will be described with reference to FIG. 5B.

FIG. 5B is an exploded perspective view of a partial area of the semiconductor memory device of FIG. 5A.

Referring to FIG. 5B, the first gate patterns 41′ may include a first tubular gate pattern 41T1′, a second tubular gate pattern 41T2′, a third tubular gate pattern 41T3′, and a fourth tubular gate pattern 41T4′.

The first tubular gate pattern 41T1′ and the second tubular gate pattern 41T2′ may be respectively arranged in a first row and a second row of the first gate patterns 41′ neighboring each other. The third tubular gate pattern 41T3′ and the fourth tubular gate pattern 41T4′ may be respectively arranged in a third row and a fourth row of the first gate patterns 41′. The first row and the second row may be disposed between the third row and the fourth row.

The vertical portion 43P1 of the separation insulating pattern 43 may be disposed between the first row and the second row.

The first tubular gate pattern 41T1′ may include a first portion T1A′ and a second portion T1B′, and the second tubular gate pattern 41T2′ may also include a first portion T2A′ and a second portion T2B′. The first portions T1A′ and T2A′ of the first and second tubular gate patterns 41T1′ and 41T2′ may come into contact with the separation insulating pattern 43. The second portions T1B′ and T2B′ of the first and second tubular gate patterns 41T1′ and 41T2′ may come into contact with the first and second line-shaped gate patterns 45L1′ and 45L2′, respectively. The first portions T1A′ and T2A′ may protrude higher than the second portions T1B′ and T2B′ in a Z axis direction. In this way, each of the first and second tubular gate patterns 41T1′ and 41T2′ may be defined as an asymmetric gate pattern. The first portions T1A′ and T2A′ may protrude higher than the third and fourth tubular gate patterns 41T 3′ and 41T4′ in the Z axis direction.

The first line-shaped gate pattern 45L1′ and the second line-shaped gate pattern 45L2′ may be disposed on the horizontal portion 43P2 of the separation insulating pattern 43. The first groove G1 and the second groove G2 may be respectively formed in both sidewalls of the vertical portion 43P1 of the separation insulating pattern 43. The third groove G3 and the fourth groove G4 may be respectively formed in the sidewalls of the first and second line-shaped gate patterns 45L1′ and 45L2′. The first groove G1 of the separation insulating pattern 43 may be disposed to face the third groove G3 of the first line shaped gate pattern 45L1′. The second groove G2 of the separation insulating pattern 43 may be disposed to face the fourth groove G4 of the second line shaped gate pattern 45L2′.

The first portions T1A′ and T2A′ of the first and second tubular gate patterns 41T1′ and 41T2′ may be inserted into the first groove G1 and the second groove G2, respectively. The second portions T1B′ and T2B′ of the first and second tubular gate patterns 41T1′ and 41T2′ may be inserted into the third groove G3 and the fourth groove G4, respectively.

The first line-shaped gate pattern 45L1′ and the second line-shaped gate pattern 45L2′ may include first holes 45H. Some of the third and fourth tubular gate patterns 41T3′ and 41T4′ may be inserted into the first holes 45H.

The horizontal portion 43P2 of the separation insulating pattern 43 may be penetrated by the second holes 43H. Lower portions of the first to fourth tubular gate patterns 41T1′, 41T2′, 41T3′, and 41T4′ may be inserted into the second holes 43H.

A portion of the gate insulating layer 35 and the upper channel portion CH2 may be inserted into a central area of each of the first to fourth tubular gate patterns 41T1′, 41T2′, 41T3′, and 41T4′.

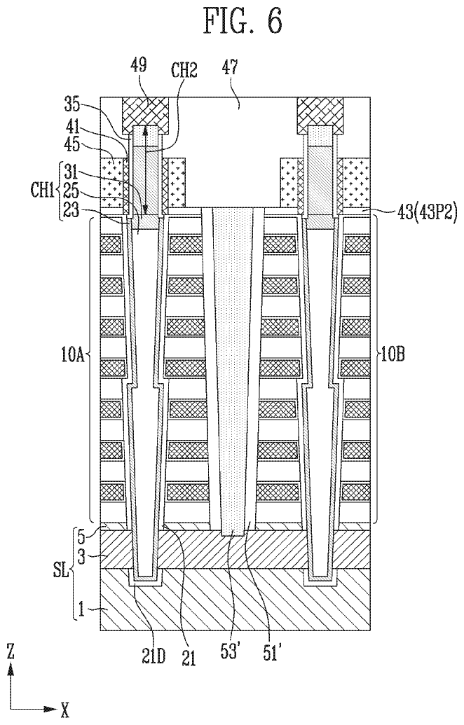

FIG. 6 is a sectional view of a semiconductor memory device according to an embodiment of the present disclosure. FIG. 6 illustrates a modification of the sidewall insulating layer 51′ and the vertical source contact 53′. Hereinafter, repeated descriptions of overlapping components will be omitted.

Referring to FIG. 6, the semiconductor memory device may include a source line SL, stacked bodies 10A and 10B neighboring each other, a sidewall insulating layer 51′, a vertical source contact 53′, a memory layer 21, a dummy memory layer 21D, a lower channel portion CH1, a separation insulating pattern 43, a upper channel portion CH2, a gate insulating layer 35, a first gate pattern 41, a second gate pattern 45, an upper insulating layer 47, and a conductive contact 49.

The source line SL may include a first doped semiconductor layer 1, a channel contact layer 3, and a second doped semiconductor layer 5.

The stacked bodies 10A and 10B may be disposed on the source line SL.

The sidewall insulating layer 51′ may be formed on a sidewall of each of the stacked bodies 10A and 10B. The vertical source contact 53′ may extend from the channel contact layer 3 in a Z axis direction.

The lower channel portion CH1 may include a channel layer 23, a core insulating layer 25, and a semiconductor pattern 31. The sidewall insulating layer 51′ and the vertical source contact 53′may protrude higher than the lower channel portions CH1 in a Z axis direction. In an embodiment, the sidewall insulating layer 51′ and the vertical source contact 53′ may pass through the horizontal portion 43P2 of the separation insulating pattern 43.

The top surface of each of the sidewall insulating layer 51′ and the vertical source contact 53′ may be disposed at a level lower than that of the top surface of each of the upper channel portion CH2, the gate insulating layer 35, the first gate pattern 41, and the second gate pattern 45. The upper insulating layer 47 may cover the top surface of each of the sidewall insulating layer 51′ and the vertical source contact 53′.

Hereinafter, methods of manufacturing a semiconductor memory device according to embodiments of the present disclosure will be described.

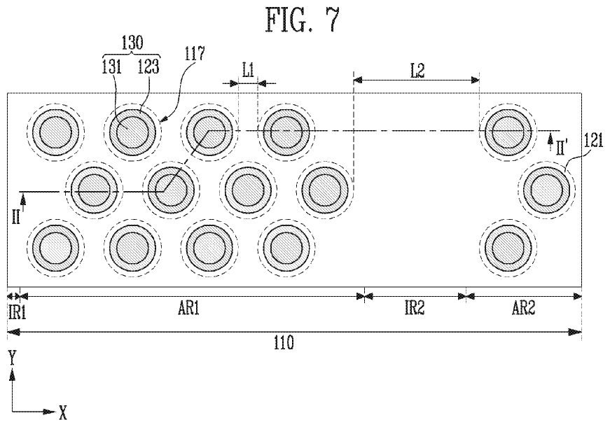

FIG. 7 is a plan view illustrating a stacked body, a memory layer, and lower channel portions.

Referring to FIG. 7, a stacked body 110 may extend along an X-Y plane. The stacked body 110 may include isolation regions IR1 and IR2 and array regions AR1 and AR2. The isolation regions IR1 and IR2 and the array regions AR1 and AR2 may extend in parallel. In the X-Y plane, the isolation regions IR1 and IR2 may be arranged to alternate with the array regions AR1 and AR2. In an embodiment, the isolation regions IR1 and IR2 and the array regions AR1 and AR2 may be alternately arranged in an X axis direction.

In each of the array regions AR1 and AR2, the stacked body 110 may be penetrated by the channel holes 117. The channel holes 117 may form a plurality of rows and a plurality of columns. A Y axis direction may be defined as a row direction, and the X axis direction may be defined as a column direction.

A memory layer 121 may be arranged on a sidewall of each of the channel holes 117.

The lower channel portions 130 may be disposed inside the respective channel holes 117. Each of the lower channel portions 130 may include a channel layer 123 and a semiconductor pattern 131.

The array regions AR1 and AR2 may include a first array region AR1 and a second array region AR2. The lower channel portions 130 may include a first group which passes through the stacked body 110 in the first array region AR1, and a second group which passes through the stacked body 110 in the second array region AR2. A distance L1 between the lower channel portions 130 in each group may be shorter than a distance L2 between the first group of the lower channel portions 130 and the second group of the lower channel portions 130.

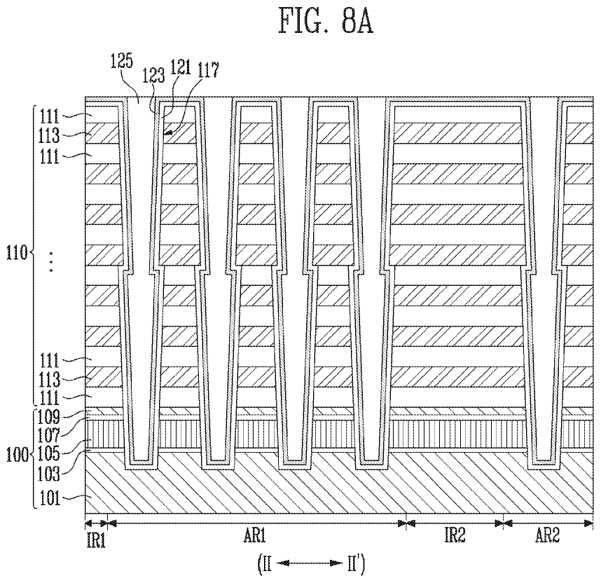

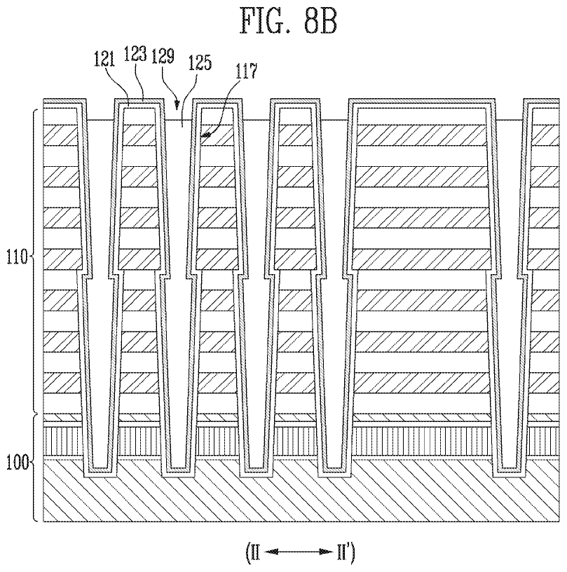

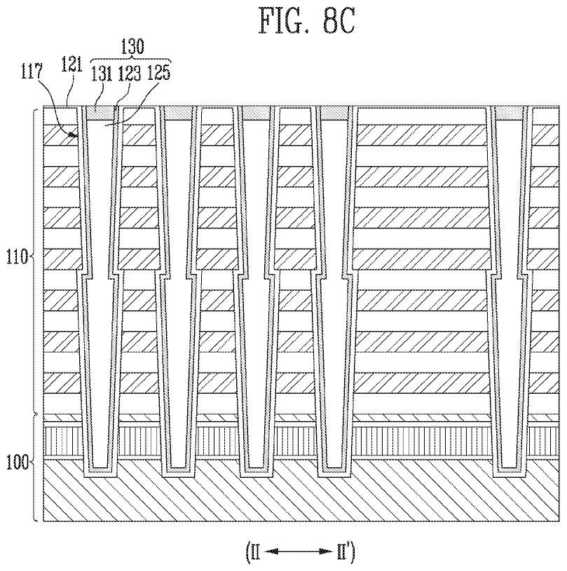

FIGS. 8A, 8B, and 8C are sectional views illustrating an embodiment of a method of manufacturing the stacked body, the memory layer, and the lower channel portions. FIGS. 8A, 8B, and 8C are sectional views taken along line II-II′ of FIG. 7.

Referring to FIG. 8A, the stacked body 110 may be formed on a preliminary source structure 100.

In an embodiment, the preliminary source structure 100 may include a first doped semiconductor layer 101, a first source protective layer 103, a sacrificial source layer 105, a second source protective layer 107, and a preliminary source layer 109 which are sequentially stacked. The first doped semiconductor layer 101 may include impurities of at least one of n type and p type. In an embodiment, the first doped semiconductor layer 101 may include n-type doped silicon. The first source protective layer 103 and the second source protective layer 107 may be formed of a material that is capable of protecting the first doped semiconductor layer 101 and the preliminary source layer 109 during a subsequent etching process for selectively removing the sacrificial source layer 105. In an embodiment, the first source protective layer 103 and the second source protective layer 107 may include oxide. The sacrificial source layer 105 may include silicon. The preliminary source layer 109 may include undoped silicon or doped silicon.

The stacked body 110 may include first material layers 111 and second material layers 113 which are alternately stacked on the preliminary source structure 100. The second material layers 113 may be formed of a material different from that of the first material layers 111. In an embodiment, the first material layers 111 may include oxide, and the second material layers 113 may include nitride.

After the stacked body 110 has been formed, the channel holes 117 passing through the stacked body 110 may be formed. The channel holes 117 may extend to the inside of the first doped semiconductor layer 101 of the preliminary source structure 100.

Then, the memory layer 121 may be formed on the surface of each of the channel holes 117. The memory layer 121 may include a tunnel insulating layer TL, a data storage layer DL, and a first blocking insulating layer BI1 which are illustrated in FIG. 2B. The memory layer 121 may extend to overlap a top surface of the stacked body 110.

Thereafter, the channel layer 123 may be formed on the memory layer 121. The channel layer 123 may include a semiconductor material such as silicon. The channel layer 123 may extend to overlap a top surface of the stacked body 110.

Next, a central area of each of the channel holes 117 defined by the channel layer 123 may be filled with a core insulting layer 125.

Referring to FIG. 8B, a portion of the core insulating layer 125 may be etched. In this way, a recess area 129 may be defined in the top of each of the channel holes 117.

Referring to FIG. 8C, the recess area 129 illustrated in FIG. 8B may be filled with a semiconductor pattern 131. A process for forming the semiconductor pattern 131 may include the step of applying a semiconductor material onto the channel layer 123 to fill the recess area 129 of FIG. 8B and the step of performing a planarization process so that the semiconductor material remains only in the channel holes 117.

The process for planarizing the semiconductor material may be performed such that the memory layer 121 is exposed. In this way, the lower channel portions 130 may be formed in respective channel holes 117. Each of the lower channel portions 130 may include a channel layer 123, a core insulating layer 125, and a semiconductor pattern 131.

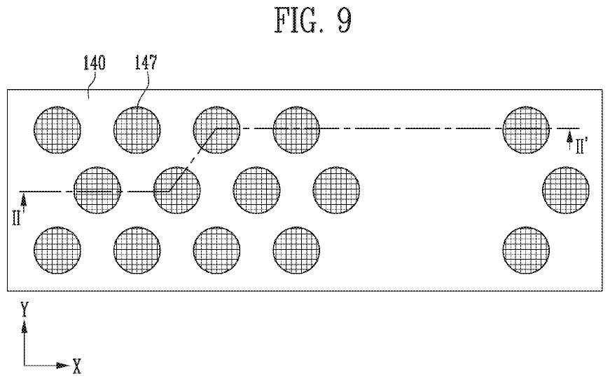

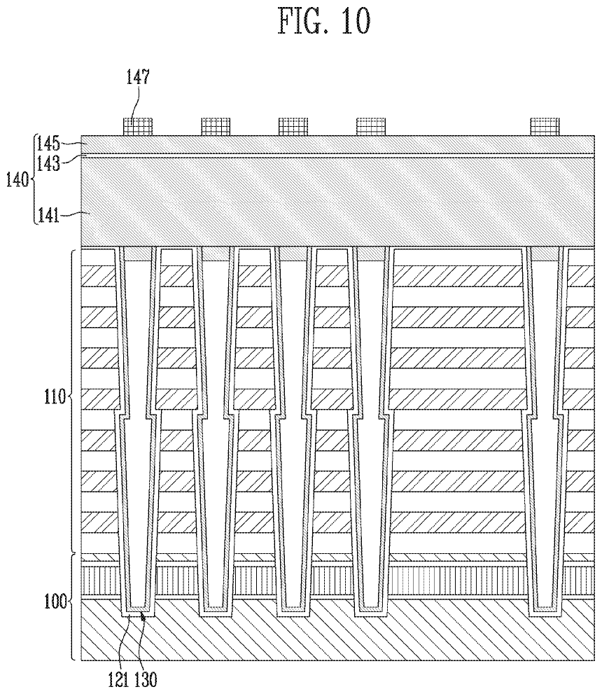

FIGS. 9 and 10 are respectively a plan view and a sectional view illustrating an embodiment of a method of manufacturing an upper stacked body and a first mask pattern. FIG. 10 is a sectional view taken along line II-II′ of FIG. 9.

Referring to FIGS. 9 and 10, an upper stacked body 140 overlapping the lower channel portions 130 and the stacked body 110 may be formed. Thereafter, a first mask pattern 147 overlapping each of the lower channel portions 130 may be formed on the upper stacked body 140.

The upper stacked body 140 may include a semiconductor layer 141, a protective layer 143, and a sacrificial layer 145. The semiconductor layer 141 may overlap the stacked body 110 and the lower channel portions 130. The semiconductor layer 141 may be formed of a substantially intrinsic semiconductor material. The protective layer 143 may be formed on the semiconductor layer 141. The sacrificial layer 145 may be formed on the protective layer 143. The protective layer 143 may include an insulating material having etch selectivity with respect to the semiconductor layer 141 and the sacrificial layer 145. In an embodiment, the protective layer 143 may include oxide, and the semiconductor layer 141 and the sacrificial layer 145 may include silicon.

The first mask pattern 147 may be formed on the sacrificial layer 145. The first mask pattern 147 may include a material having etch selectivity with respect to the semiconductor layer 141, the protective layer 143, and the sacrificial layer 145. In embodiment, the first mask pattern 147 may include nitride.

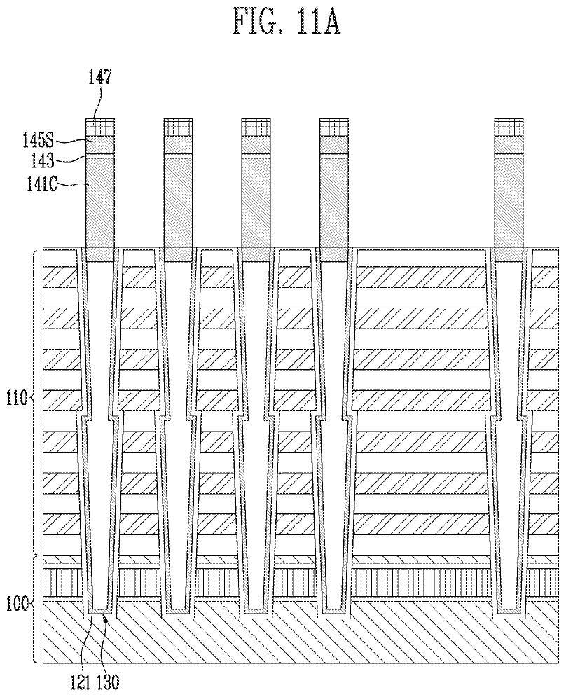

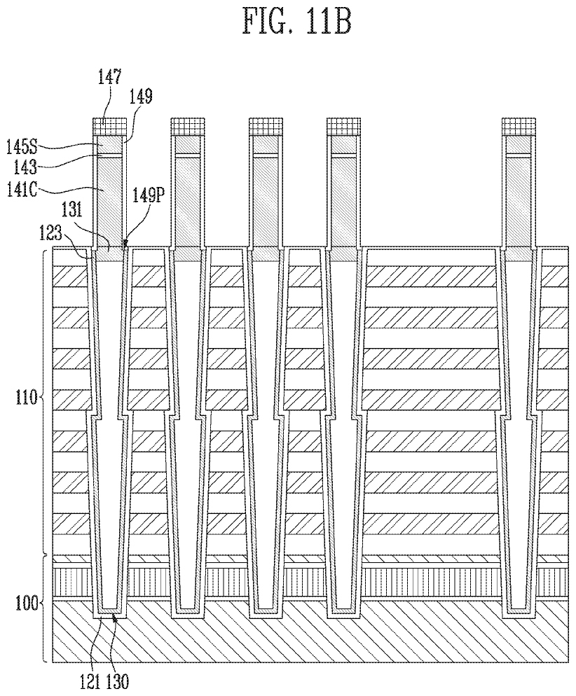

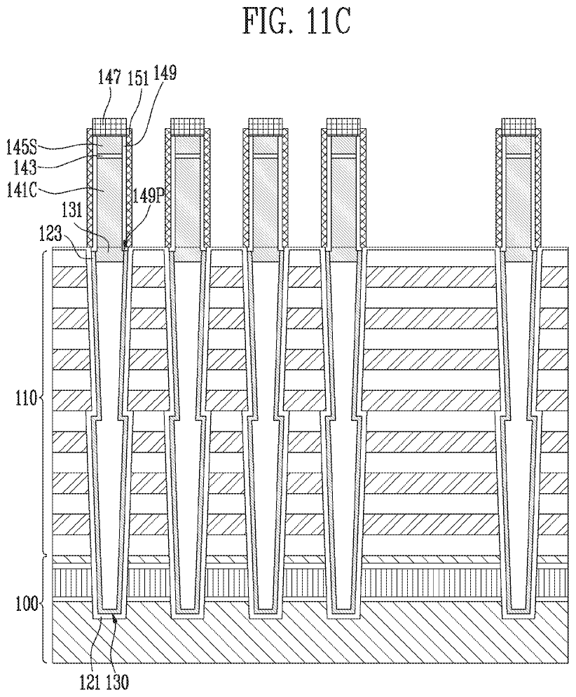

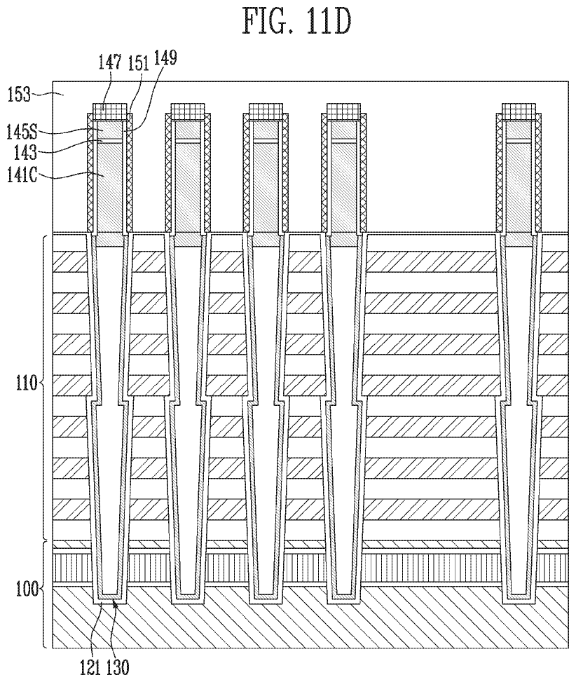

FIGS. 11A, 11B, 11C, and 11D are sectional views illustrating embodiments of subsequent processes to be performed after the first mask pattern is formed.

Referring to FIG. 11A, through an etching process that uses the first mask pattern 147 as an etching barrier, the semiconductor layer 141, the protective layer 143, and the sacrificial layer 145, illustrated in FIG. 10, may be etched. In this way, the semiconductor layer 141 illustrated in FIG. 10 may be patterned as upper channel portions 141C. Further, the sacrificial layer 145 illustrated in FIG. 10 may be patterned as sacrificial patterns 145S.

The upper channel portions 141C may be spaced apart from each other. The upper channel portions 141C may be disposed on the lower channel portions 130, respectively. In accordance with an embodiment of the present disclosure, the upper channel portions 141C may be defined as having a length that is as uniform as the thickness of the semiconductor layer 141 illustrated in FIG. 10.

The sacrificial patterns 145S may be arranged on the upper channel portions 141C, respectively. The protective layer 143 may remain between the upper channel portions 141C and the sacrificial patterns 145S.

In an embodiment, the width of each of the upper channel portions 141C may be controlled to be less than that of each of the lower channel portions 130. In this case, the edge of the top surface of each of the lower channel portions 130 may be exposed.

Referring to FIG. 11B, gate insulating layers 149 may be formed through an oxidation process. The gate insulating layers 149 may be formed on sidewalls of the upper channel portions 141C, and may extend onto the sidewalls of the sacrificial patterns 145S, respectively.

During the oxidation process, a portion of the channel layer 123 of each of the lower channel portions 130 and a portion of the semiconductor pattern 131 may be oxidized. In this way, each of the gate insulating layers 149 may include a protrusion 149P extending along the edge of the top surface of each of the lower channel portions 130.

Referring to FIG. 11C, first gate patterns 151 enclosing respective sidewalls of the gate insulating layers 149 may be formed.

A process for forming the first gate patterns 151 may include the step of conformally depositing a conductive barrier layer and the step of etching the conductive barrier layer through an etch-back process. The conductive barrier layer may include titanium, titanium nitride, etc.

The protrusion 149P of the gate insulating layer 149 allows the first gate pattern 151 to be spaced apart from the channel layer 123 and the semiconductor pattern 131 of the lower channel portion 130.

Referring to FIG. 11D, an insulating layer 153 may be formed on the stacked body 110. The insulating layer 153 may cover the first gate patterns 151 and the first mask pattern 147. The insulating layer 153 may be formed to fill space between the first gate patterns 151.

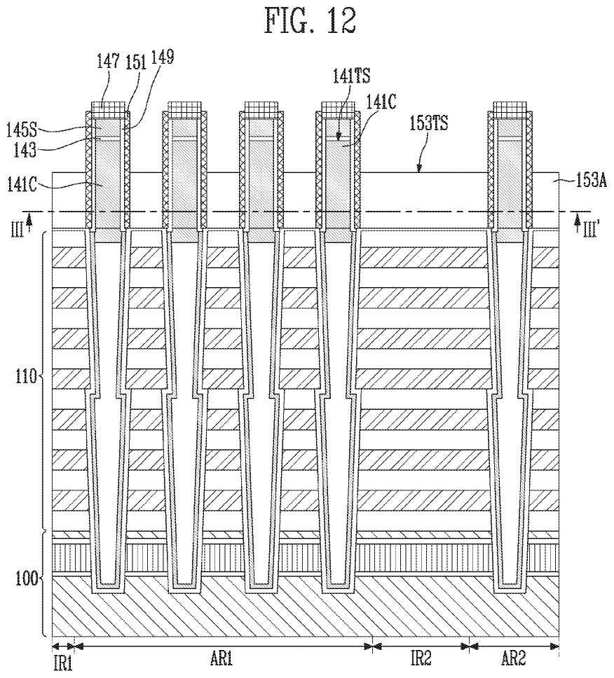

FIG. 12 is a sectional view illustrating an embodiment of a subsequent process to be performed after the insulating layer is formed.

Referring to FIG. 12, a portion of the insulating layer 153 illustrated in FIG. 11D may be etched, and thus the thickness of the insulating layer 153 may be reduced. The insulating layer 153A, remaining after the etching process, may have a top surface 153TS disposed at a level lower than that of the top surface 141TS of each of the upper channel portions 141C. The remaining insulating layer 153A may fill space between lower portions of the first gate patterns 151, and may overlap the stacked body 110.

The first gate patterns 151 may be divided into a plurality of groups. In an embodiment, the first gate patterns 151 may include a first group disposed on the stacked body 110 in a first array region AR1 and a second group disposed on the stacked body 110 in a second array region AR2.

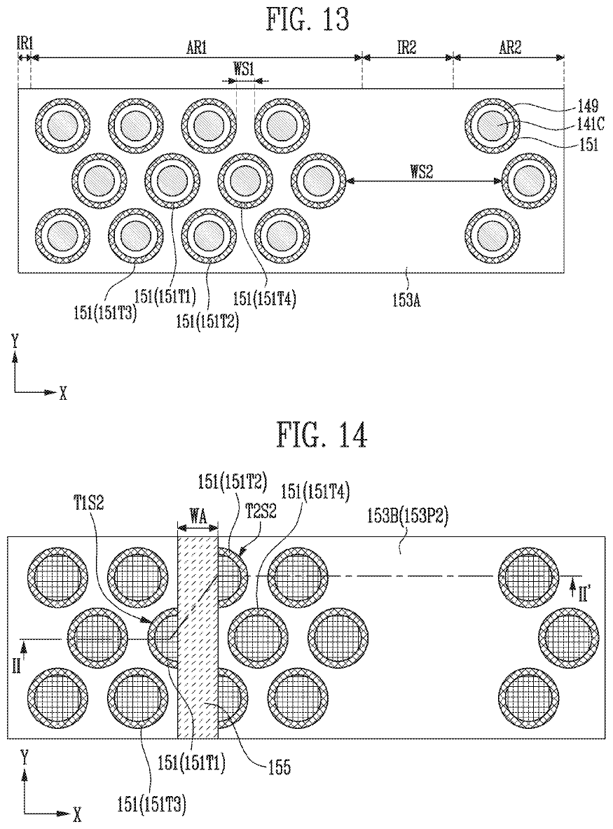

FIG. 13 is a plan view taken along line III-III′ of FIG. 12.

Referring to FIG. 13, a first space WS1 may be defined between the first gate patterns 151 in each group. A second space WS2 may be defined between the first group and the second group of the first gate patterns 151. The first space WS1 may be defined as having a width less than that of the second space WS2.

The first gate patterns 151 may be tubular gate patterns which enclose respective sidewalls of the gate insulating layers 149. The first gate patterns 151 in each group may be arranged in two or more rows. In an embodiment, the first gate patterns 151 may include a first tubular gate pattern 151T1 arranged in a first row, a second tubular gate pattern 151T2 arranged in a second row, a third tubular gate pattern 151T3 arranged in a third row, and a fourth tubular gate pattern 151T4 arranged in a fourth row.

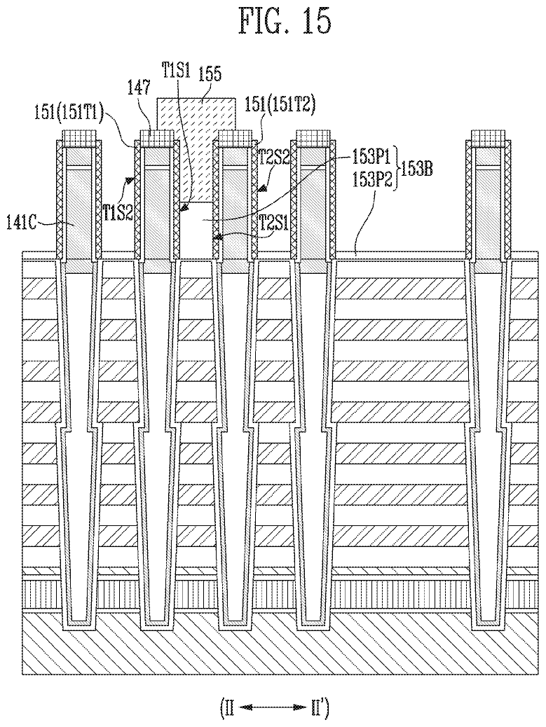

FIGS. 14 and 15 are respectively a plan view and a sectional view illustrating an embodiment of a method of manufacturing a separation insulating pattern.

Referring to FIGS. 14 and 15, a second mask pattern 155 may be formed on the insulating layer 153A illustrated in FIGS. 12 and 13. The second mask pattern 155 may be a photoresist pattern.

The second mask pattern 155 may overlap a portion of the insulating layer 153A illustrated in FIGS. 12 and 13. For example, the second mask pattern 155 may overlap a portion of the insulating layer 153A between the first tubular gate pattern 151T1 and the second tubular gate pattern 151T2.

The width WA of the second mask pattern 155 may be defined as a value greater than a separation distance between the first tubular gate pattern 151T1 and the second tubular gate pattern 151T2. The second mask pattern 155 may overlap a first sidewall T1S1 of the first tubular gate pattern 151T1 and a first sidewall T2S1 of the second tubular gate pattern 151T2. A second sidewall T1S2 of the first tubular gate pattern 151T1 and a second sidewall T2S2 of the second tubular gate pattern 151T2 may be defined as sidewalls which do not overlap the second mask pattern 155.

Next, the insulating layer may be etched through an etching process that uses the second mask pattern 155 as an etching barrier, and thus a separation insulating pattern 153B may be defined. The separation insulating pattern 153B may include a vertical portion 153P1 and a horizontal portion 153P2 extending to both sides of the vertical portion 153P1. The vertical portion 153P1 may be defined as a portion between the first tubular gate pattern 151T1 and the second tubular gate pattern 151T2. The thickness of the horizontal portion 153P2 may be defined as being less than that of the vertical portion 153P1.

The vertical portion 153P1 of the separation insulating pattern 153B may come into contact with the first sidewall T1S1 of the first tubular gate pattern 151T1 and the first sidewall T2S1 of the second tubular gate pattern 151T2. A portion of each of the second sidewall T1S2 of the first tubular gate pattern 151T1 and the second sidewall T2S2 of the second tubular gate pattern 151T2 may be exposed to the outside of the separation insulating pattern 153B. The third tubular gate pattern 151T3 and the fourth tubular gate pattern 151T4 may also be exposed to the outside of the separation insulating pattern 153B.

The second mask pattern 155 may be removed after the separation insulating pattern 153B has been formed.

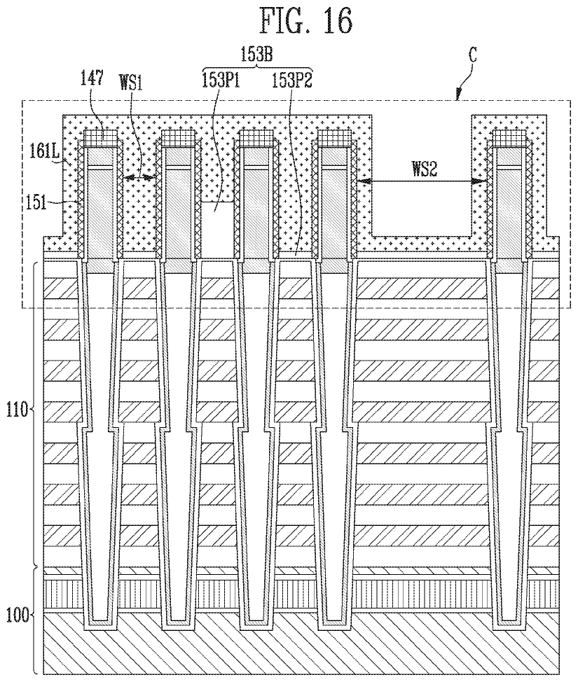

FIG. 16 is a sectional view illustrating an embodiment of a method of manufacturing a conductive layer.

Referring to FIG. 16, a conductive layer 161L may be formed on the separation insulating pattern 153B. The conductive layer 161L may include a metal layer formed of tungsten or the like. The conductive layer 161L may be formed to fill a first space WS1 between the first gate patterns 151. The conductive layer 161L may cover the vertical portion 153P1 of the separation insulating pattern 153B and the first mask pattern 147. The conductive layer 161L may be conformally formed in a second space WS2 having a width greater than that of the first space WS1. A central area of the second space WS2 may be opened without being filled with the conductive layer 161L.

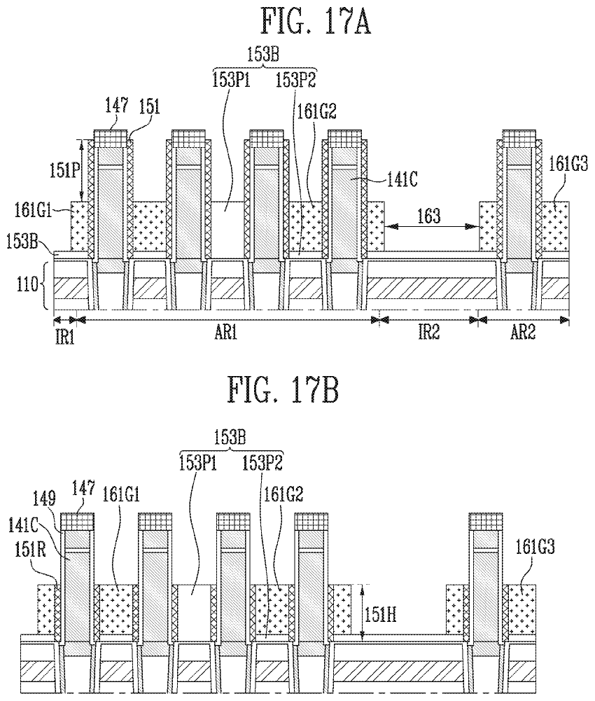

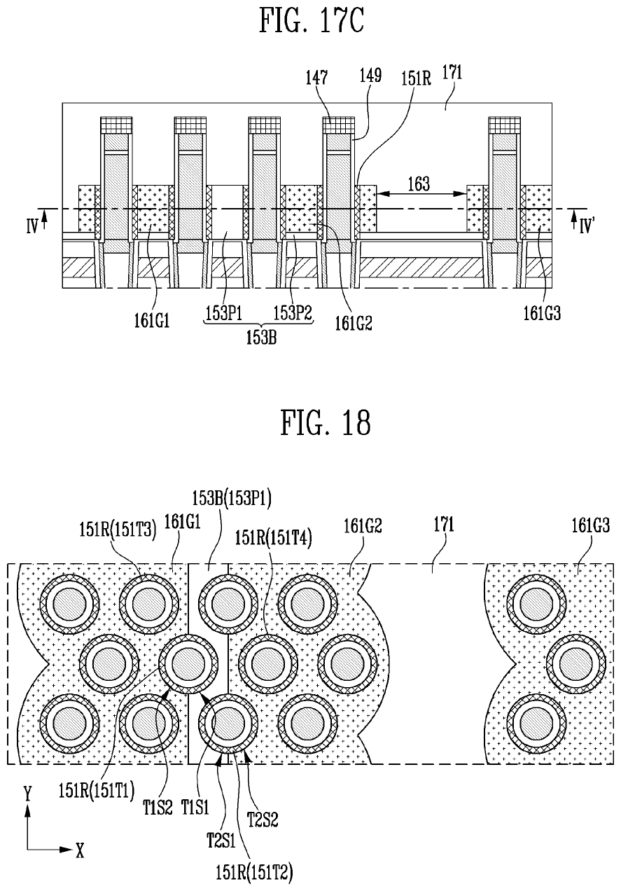

FIGS. 17A, 17B, and 17C are enlarged sectional views illustrating embodiments of subsequent processes for area C illustrated in FIG. 16.

Referring to FIG. 17A, a portion of the conductive layer 161L illustrated in FIG. 16 may be etched through an etch-back process or the like. The conductive layer 161L may be etched such that the separation insulating pattern 153B is exposed. Second gate patterns 161G1, 161G2, and 161G3 which are separated from each other may be formed through the process for etching the conductive layer 161L. The second gate patterns 161G1, 161G2, and 161G3 may be patterned in line shapes.

In accordance with an embodiment of the present disclosure, even if an etching barrier pattern is not separately formed on the conductive layer 161L illustrated in FIG. 16, the second gate patterns 161G1, 161G2, and 161G3 which are separated from each other may be formed using the etch-back process.

The vertical portion 153P1 of the separation insulating pattern 153B may be disposed between the second gate patterns 161G1, 161G 2, and 161G3 or a trench 163 may be defined between the second gate patterns 161G1, 161G2, and 161G3. In an embodiment, the second gate patterns 161G1, 161G2, and 161G3 may include the first line-shaped gate pattern 161G1, the second line-shaped gate pattern 161G2, and the third line-shaped gate pattern 161G3. The first line-shaped gate pattern 161G1 and the second line-shaped gate pattern 161G2 may be arranged on the stacked body 110 in the first array region AR1, and the third line-shaped gate pattern 161G3 may be arranged on the stacked body 110 in the second array region AR2. The first line-shaped gate pattern 161G1 may be spaced apart from the second line-shaped gate pattern 161G2 through the vertical portion 153P1 of the separation insulating pattern 153B. The second line-shaped gate pattern 161G2 may be spaced apart from the third line-shaped gate pattern 161G3 through the trench 163.

In an embodiment, the first gate patterns 151 may have etch selectivity with respect to the conductive layer 161L illustrated in FIG. 16. Accordingly, even if the conductive layer 161L illustrated in FIG. 16 is etched, the first gate patterns 151 may not be lost, and may remain while protruding higher than the second gate patterns 161G1, 161G2, and 161G3 in a longitudinal direction of the upper channel portions 141C. Hereinafter, portions of the first gate patterns 151 protruding higher than the second gate patterns 161G1, 161G2, and 161G3 in the longitudinal direction of the upper channel portions 141C are defined as protrusions 151P. The protrusions 151P may protrude higher than the vertical portion 153P1 of the separation insulating pattern 153B in the longitudinal direction of the upper channel portions 141C.

Referring to FIG. 17B, the protrusions 151P illustrated in FIG. 17A may be selectively removed through wet etching or the like. A gate length may be defined by the height 151H of the first gate patterns remaining after the protrusions 151P of FIG. 17A have been removed.

The first gate patterns 151R may be protected by the second gate patterns 161G1, 161G2, and 161G3 or by the vertical portion 153P1 of the separation insulating pattern 153B. In this way, the first gate patterns 151R may provide a gate-all-around structure which encloses each of the upper channel portions 141C.

After the protrusions 151P illustrated in FIG. 17A have been removed, the gate insulating layers 149 may remain while protruding higher than the first gate patterns 151R in the longitudinal direction of the upper channel portions 141C.

Referring to FIG. 17C, an upper insulating layer 171 may be formed to cover the first gate patterns 151R, the second gate patterns 161G1, 161G2, and 161G3, and the separation insulating pattern 153B. The upper insulating layer 171 may fill the trench 163. The upper insulating layer 171 may enclose the gate insulating layers 149. The upper insulating layer 171 may extend onto the first mask pattern 147. The upper insulating

layer 171 may include oxide.

FIG. 18 is a plan view taken along line IV-IV′ of FIG. 17C.

Referring to FIG. 18, tubular gate patterns arranged in two or more neighboring rows, among the first gate patterns 151R, may be coupled to each other by each of the second gate patterns 161G1, 161G 2, and 161G3.

In an embodiment, the first line-shaped gate pattern 161G1 may couple the first tubular gate pattern 151T1 arranged in a first row to the third tubular gate pattern 151T3 arranged in a third row. In an embodiment, the second line-shaped gate pattern 161G2 may couple the second tubular gate pattern 151T2 arranged in a second row to the fourth tubular gate pattern 151T4 arranged in a fourth row.

The first line-shaped gate pattern 161G1 and the second line-shaped gate pattern 161G2 which are arranged on both sides of the vertical portion 153P1 of the separation insulating pattern 153B may come into contact with not only the separation insulating pattern 153B but also some of the first gate patterns 151R. In an embodiment, the first line-shaped gate pattern 161G1 may come into contact with the second sidewall T1S2 of the first tubular gate pattern 151T1. Further, the second line-shaped gate pattern 161G2 may come into contact with the second sidewall T2S2 of the second tubular gate pattern 151T2.

The vertical portion 153P1 of the separation insulating pattern 153B may remain while contacting the first sidewall T1S1 of the first tubular gate pattern 151T1 and the first sidewall T2S1 of the second tubular gate pattern 151T2.

The upper insulating layer 171 may be disposed between the second line-shaped gate pattern 161G2 and the third line-shaped gate pattern 161G3.

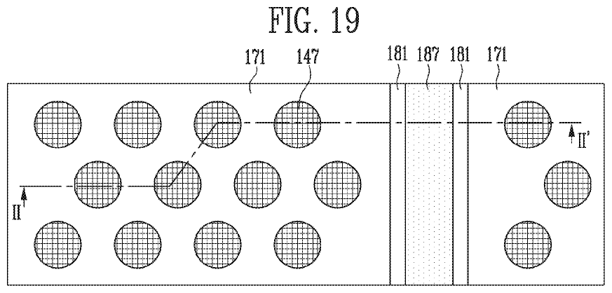

FIG. 19 is a plan view illustrating a first mask pattern, an upper insulating layer, a sidewall insulating layer, and a vertical source contact.

Referring to FIG. 19, after the structure illustrated in FIG. 17C has been formed, a sidewall insulating layer 181 and a vertical source contact 187 may be formed. Thereafter, a portion of the upper insulating layer 171 may be removed such that the first mask pattern 147 is exposed. Before the sidewall insulating layer 181 is formed, a replace process for forming conductive patterns may be performed.

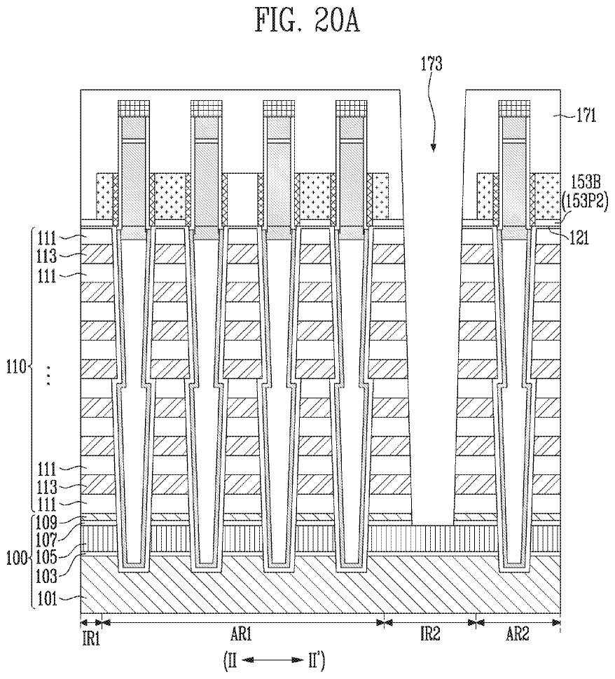

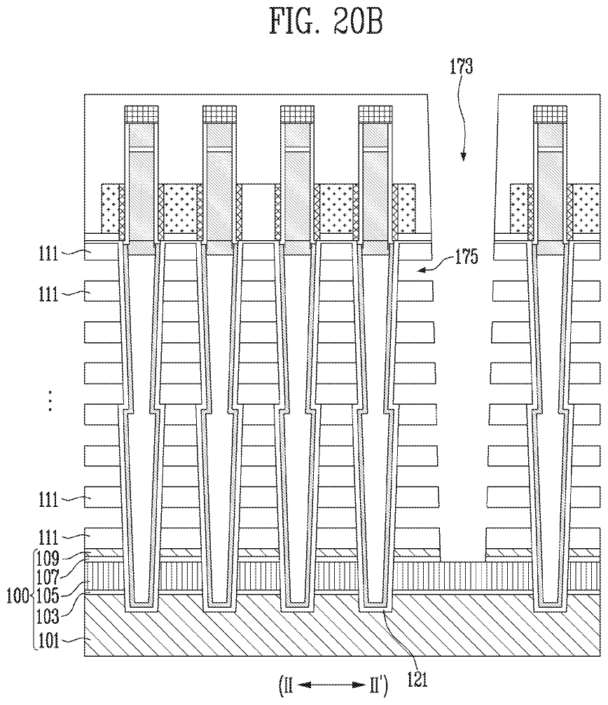

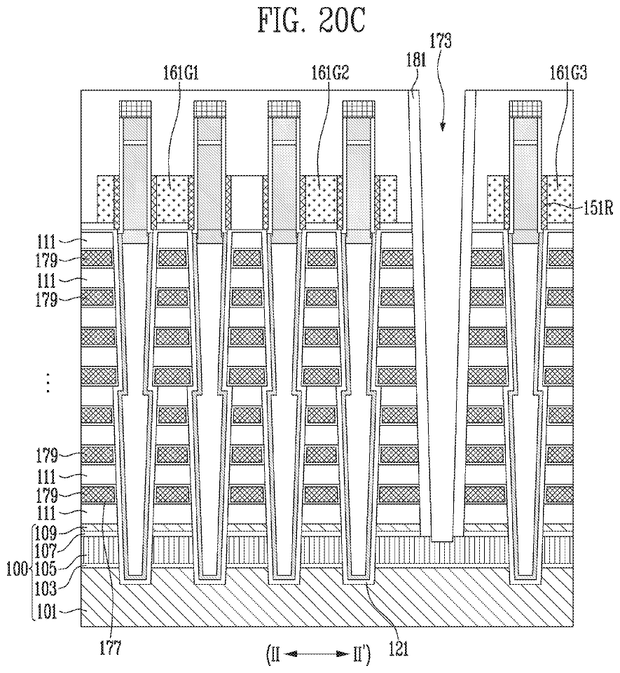

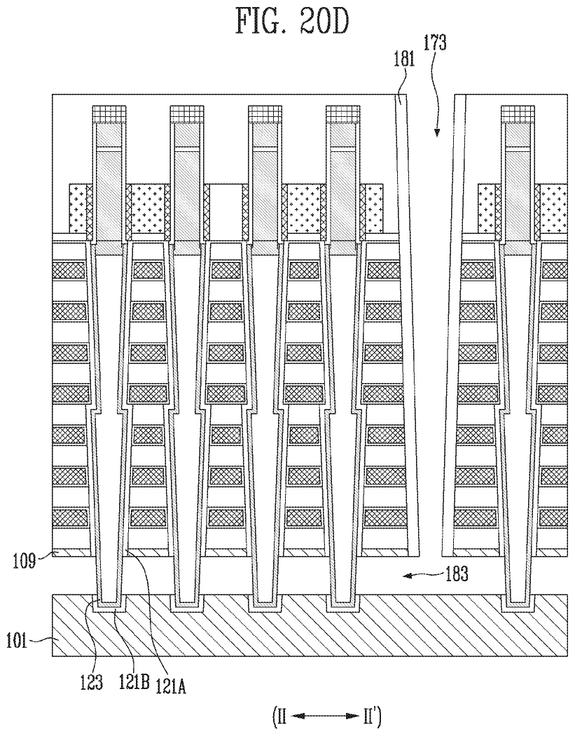

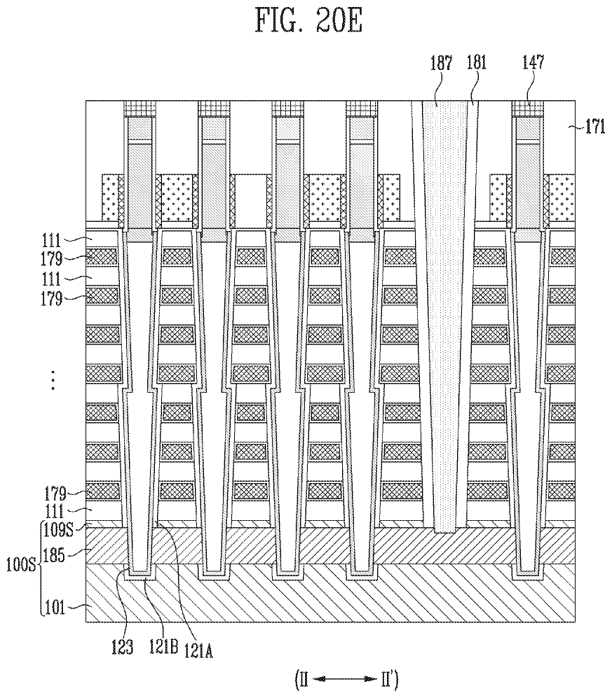

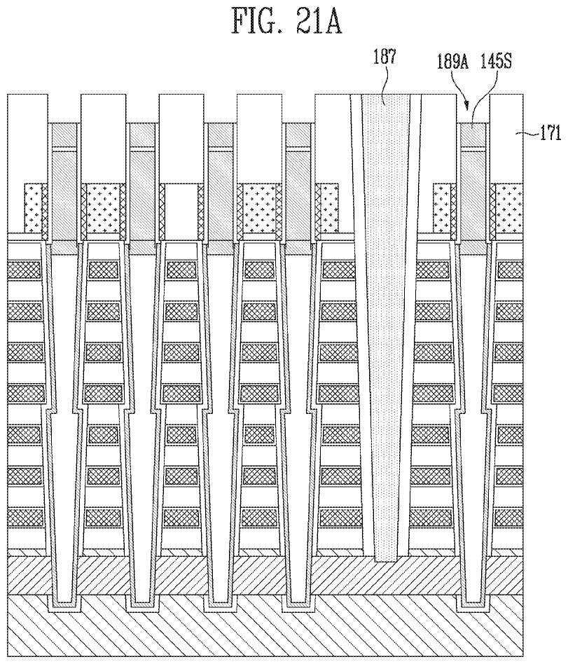

FIGS. 20A, 20B, 20C, 20D, and 20E are sectional views illustrating embodiments of a method of manufacturing the structure of FIG. 19.

Referring to FIG. 20A, a slit 173 may be formed to pass through the upper insulating layer 171 and the stacked body 110. The memory layer 121 and the horizontal portion 153P2 of the separation insulating pattern 153B, which are disposed between the upper insulating layer 171 and the stacked body 110 and the stacked body 110, may be penetrated by the slit 173.S

The slit 173 may pass through the preliminary source layer 109 and the second source protective layer 107 of the preliminary source structure 100. A bottom surface of the slit 173 may be defined along the surface of the sacrificial source layer 105.

Referring to FIG. 20B, second material layers 113 illustrated in FIG. 20A may be removed through the slit 173. In this way, openings 175 may be defined between the first material layers 111. The memory layer 121 may be exposed through the openings 175.

Referring to FIG. 20C, a blocking insulating layer 177 may be formed along the surface of each of the openings 175 illustrated in FIG. 20B. The blocking insulating layer 177 may include metal oxide. In an embodiment, the blocking insulating layer 177 may include aluminum oxide (Al₂O₃). After the blocking insulating layer 177 has been deposited, an annealing process may be performed on the blocking insulating layer 177. The blocking insulating layer 177 may be conformally formed along respective surfaces of the openings 175 illustrated in FIG. 20B so that the blocking insulating layer 177 does not fill respective central areas of the openings 175 illustrated in FIG. 20B.

Thereafter, conductive patterns 179 may be formed. The conductive patterns 179 may fill respective central areas of the openings 175 illustrated in FIG. 20B. The conductive patterns 179 may be separated from each other through the slit 173 and the first material layers 111.

Thereafter, the sidewall insulating layer 181 may be formed on the sidewall of the slit 173.

Referring to FIG. 20D, the sacrificial source layer 105 illustrated in FIG. 20C may be removed through the slit 173. Next, a portion of the memory layer 121 illustrated in FIG. 20C may be removed. While the portion of the memory layer 121 illustrated in FIG. 20C is removed, the first source protective layer 103 and the second source protective layer 107, which are illustrated in FIG. 20C, may be removed.

As described above, as the sacrificial source layer 105, the portion of the memory layer 121, the first source protective layer 103, and the second source protective layer 107, which are illustrated in FIG. 20C, are removed, a horizontal space 183 may be open. The sidewall of the channel layer 123, the first doped semiconductor layer 101, and the preliminary source layer 109 may be exposed through the horizontal space 183. The memory layer may be separated into a first memory layer 121A and a second memory layer 121B through the horizontal space 183. The second memory layer 121B may be defined as a dummy memory layer.

Referring to FIG. 20E, the horizontal space 183 illustrated in FIG. 20D may be filled with a channel contact layer 185. The channel contact layer 185 may include a semiconductor material including conductive impurities. The channel contact layer 185 may include conductive impurities of at least one of n type and p type. In an embodiment, the channel contact layer 185 may include n-type doped silicon.

The conductive impurities of the channel contact layer 185 may be diffused to the preliminary source layer 109 illustrated in FIG. 20D. In this way, a second doped semiconductor layer 109S of a source line 100S may be defined. The source line 100S may include the first doped semiconductor layer 101, the channel contact layer 185, and the second doped semiconductor layer 109S.

Thereafter, a vertical source contact 187, which comes into contact with the channel contact layer 185 and fills the slit 173 illustrated in FIG. 20D, may be formed. The vertical source contact 187 may include at least one of doped semiconductor, metal, metal silicide, and metal nitride.

The vertical source contact 187 may be isolated from the conductive patterns 179 by the sidewall insulating layer 181. The vertical source contact 187 and the upper insulating layer 171 may be planarized. The first mask pattern 147 may be exposed by planarizing the upper insulating layer 171. The upper insulating layer 171 may remain to enclose the sidewall of the first mask pattern 147.

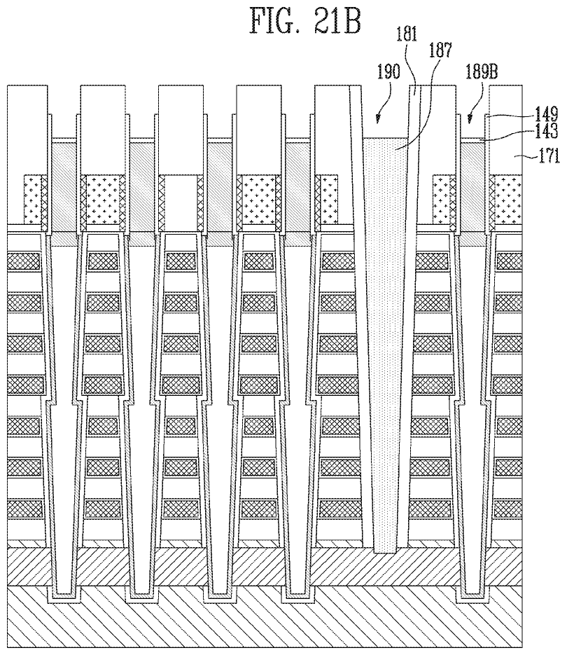

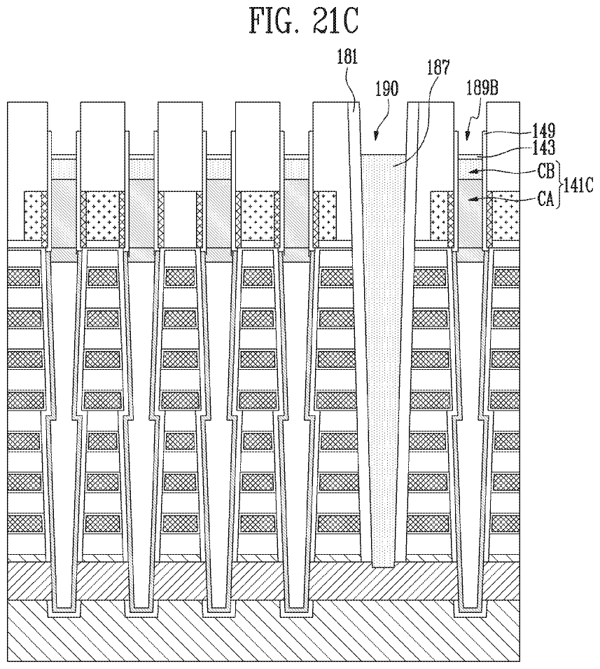

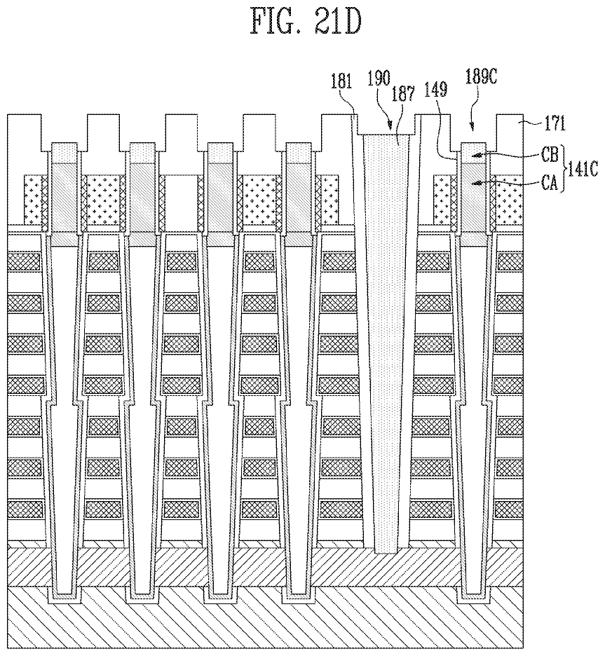

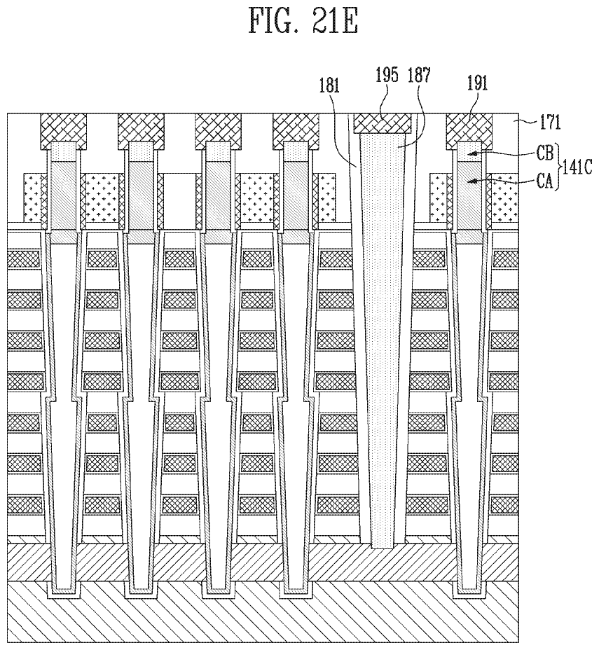

FIGS. 21A, 21B, 21C, 21D, and 21E are sectional views illustrating embodiments of subsequent processes to be performed after the structure of FIG. 20E is formed.

Referring to FIG. 21A, the first mask pattern 147 illustrated in FIG. 20E may be selectively removed. In this way, a fifth groove 189A may be defined. Each sacrificial pattern 145S may be exposed through the fifth groove 189A.

Referring to FIG. 21B, each sacrificial pattern 145S illustrated in FIG. 21A may be selectively removed. In this way, a primarily expanded fifth groove 189B may be defined. Through the primarily expanded fifth groove 189B, the top of the protective layer 143 and the top of each gate insulating layer 149 may be exposed. While the sacrificial pattern 145S is removed, a portion of the vertical source contact 187 may be removed. In this way, a recess area 190 may be defined in the top of the remaining vertical source contact 187. A sidewall of the recess area 190 may be defined along the sidewall insulating layer 181.

Referring to FIG. 21C, conductive impurities may be injected into the top of the upper channel portion 141C by performing an ion injection process through the primarily expanded fifth groove 189B. In an embodiment, n-type impurities may be injected into the top of the upper channel portion 141C. Therefore, the upper channel portion 141C may be divided into a first area CA and a second area CB. The second area CB may be defined as a doped area including conductive impurities. The first area CA may be defined as an area formed of a substantially intrinsic semiconductor material. In accordance with an embodiment of the present disclosure, the depth of the second area CB may be uniformly controlled through the ion injection process.

Referring to FIG. 21D, the protective layer 143 illustrated in FIG. 21C may be removed through the primarily expanded fifth groove 189B illustrated in FIG. 21C. Here, the top of the gate insulating layer 149 and a portion of the upper insulating layer 171 may be etched. In this way, a secondarily expanded fifth groove 189C may be defined.

Through the secondarily expanded fifth groove 189C, the second area CB of each of the upper channel portions 141C may be exposed.

While the protective layer 143 is removed, a portion of the sidewall insulating layer 181 may be etched, and thus the recess area 190 may be expanded.

Referring to FIG. 21E, the secondarily expanded fifth groove 189C, illustrated in FIG. 21D, may be filled with a conductive contact 191. Here, the recess area 190 illustrated in FIG. 21D may be filled with an upper source contact 195. The conductive contact 191 may come into contact with the second area CB of each of the upper channel portions 141C. The upper source contact 195 may come into contact with the vertical source contact 187. In accordance with an embodiment of the present disclosure, the conductive contact 191 may be automatically aligned in the secondarily expanded fifth groove 189C which opens the upper channel portions 141C. Further, the upper source contact 195 may be automatically aligned in the recess area 190.

The semiconductor memory device, described above with reference to FIG. 3A, FIG. 3B, and FIG. 4, may be provided using the processes, described above with reference to FIG. 7, FIGS. 8A to 8C, FIG. 9, FIG. 10, FIGS. 11A to 11D, FIG. 12, FIG. 13, FIG. 14, FIG. 15, FIG. 16, FIGS. 17A to 17C, FIG. 18, FIG. 19, FIGS. 20A to 20E, and FIGS. 21A to 21E.

Apart from the above-described embodiments, the first gate patterns 151R and the second gate patterns 161G1, 161G 2, and 161G 3, illustrated in FIG. 20C, may include refractory metal. The refractory metal may include titanium nitride, tantalum nitride, tungsten nitride, etc. The refractory metal has thermal stability. Therefore, although an annealing process is performed on the blocking insulating layer 177 after the first gate patterns 151R and the second gate patterns 161G1, 161G 2, and 161G 3 have been formed, degradation of electrical characteristics of the first gate patterns 151R and the second gate patterns 161G1, 161G 2, and 161G 3 caused by heat occurring in the annealing process may be mitigated.

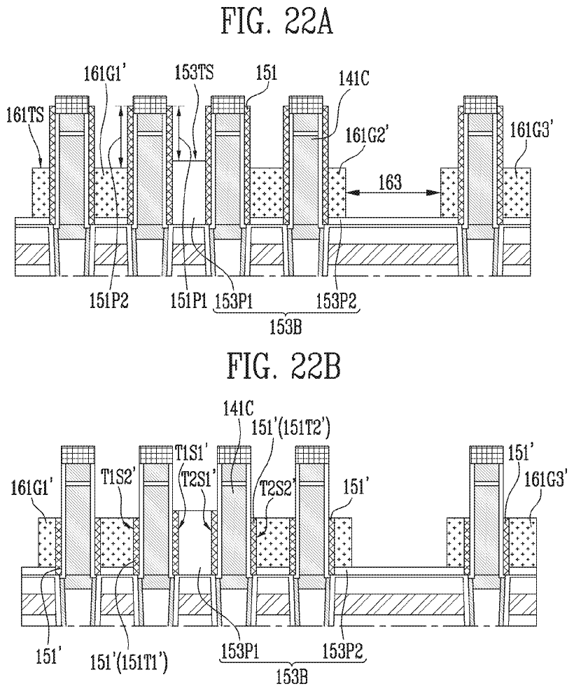

FIGS. 22A and 22B are enlarged sectional views illustrating embodiments of subsequent processes for area C illustrated in FIG. 16.

A portion of the conductive layer 161L illustrated in FIG. 16 may be etched through an etch-back process or the like. The conductive layer 161L may be etched such that the separation insulating pattern 153B is exposed. The conductive layer 161L illustrated in FIG. 16 may be separated into second gate patterns 161G1′, 161G 2′, and 161G 3′ through an etching process. Respective top surfaces 161TS of the second gate patterns 161G1′, 161G 2′, and 161G 3′ may be disposed at a level lower than that of the top surface 153TS of the vertical portion 1 53P1 of the separation insulating pattern 153B.

The first gate patterns 151 may include protrusions 151P1 and 151P2 which protrude higher than the second gate patterns 161G1′, 161G2′, and 161G3′ and the vertical portion 153P1 of the separation insulating pattern 153B in a longitudinal direction of the upper channel portions 141C. The protrusions 151P1 and 151P2 may include the first protrusion 151P1 and the second protrusion 151P2 longer than the first protrusion 151P1.

As described above with reference to FIG. 17A, the second gate patterns 161G1′, 161G2′, and 161G3′ may include the first line-shaped gate pattern 161G1′, the second line-shaped gate pattern 161G2′, and the third line-shaped gate pattern 161G3′. Also, the first line-shaped gate pattern 161G1′ may be spaced apart from the second line-shaped gate pattern 161G2′ through the vertical portion 153P1 of the separation insulating pattern 153B. Also, a trench 163 may be defined between the second line-shaped gate pattern 161G2′ and the third line-shaped gate pattern 161G3′. The horizontal portion 153P2 of the separation insulating pattern 153B may be exposed through the trench 163.

Referring to FIG. 22B, the protrusions 151P1 and 151P2 illustrated in FIG. 22A may be selectively removed through wet etching or the like. Here, some of the first gate patterns 151′ may remain as asymmetric gate patterns. In greater detail, the first row and the second row of the first gate patterns 151′ contacting the vertical portion 153P1 of the separation insulating pattern 153B may remain as asymmetric gate patterns. In other words, the first tubular gate pattern 151T1′ arranged in the first row and the second tubular gate pattern 151T2′ arranged in the second row may be asymmetric gate patterns.

The first sidewall T1S1′ of the first tubular gate pattern 151T1′ may remain while contacting the vertical portion 153P1 of the separation insulating pattern 153B, and the second sidewall T1S2′ of the first tubular gate pattern 151T1′ may remain while contacting the first line-shaped gate pattern 161G1′. The first sidewall T2S1′ of the second tubular gate pattern 151T2′ may remain while contacting the vertical portion 153P1 of the separation insulating pattern 153B, and the second sidewall T2S2′ of the second tubular gate pattern 151T2′ may remain while contacting the second line-shaped gate pattern 161G2′. The remaining first sidewalls T1S1′ and T2S1′ protrude higher than the remaining second sidewalls T1S2′ and T2S2′ in the longitudinal direction of the upper channel portion 141C, and thus the first tubular gate pattern 151T1′ and the second tubular gate pattern 151T2′ may be defined as asymmetric gate patterns.

The semiconductor memory device, described above with reference to FIGS. 5A and 5B, may be provided using the processes described above with reference to FIGS. 22A and 22B.

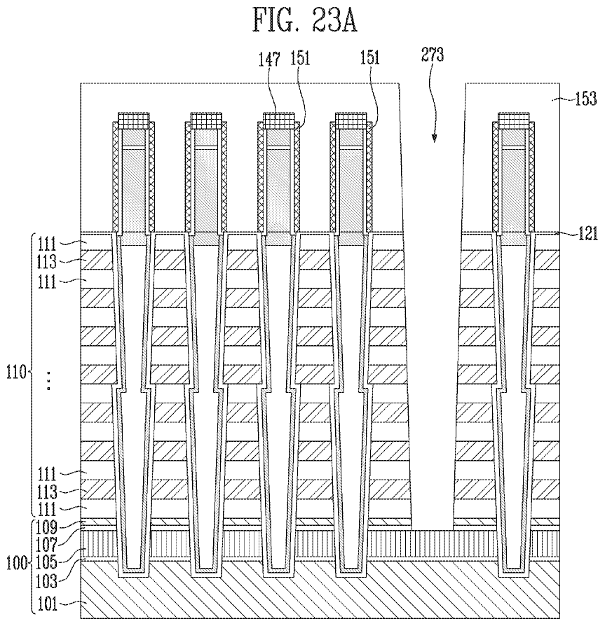

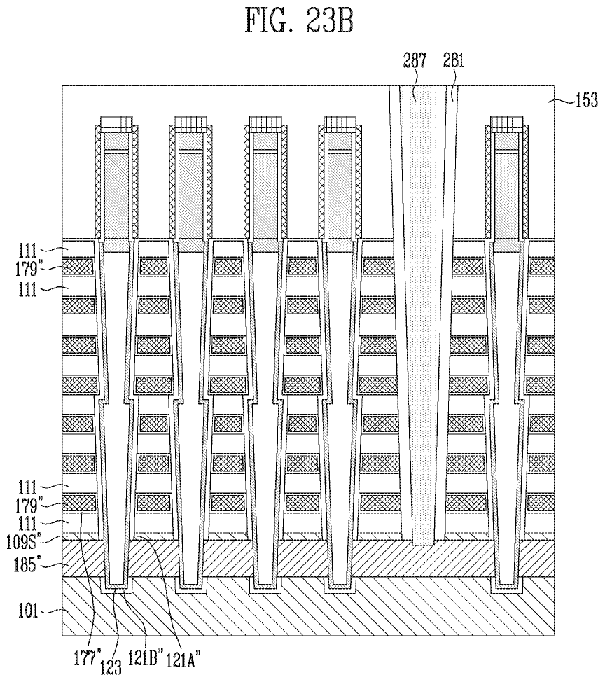

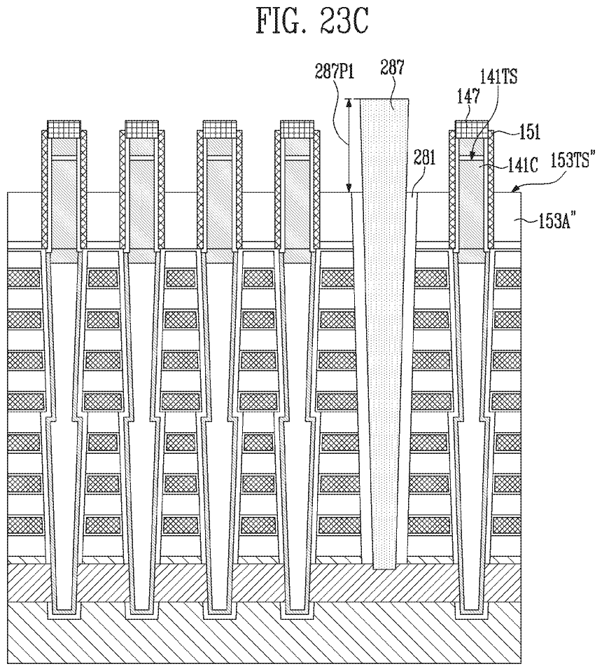

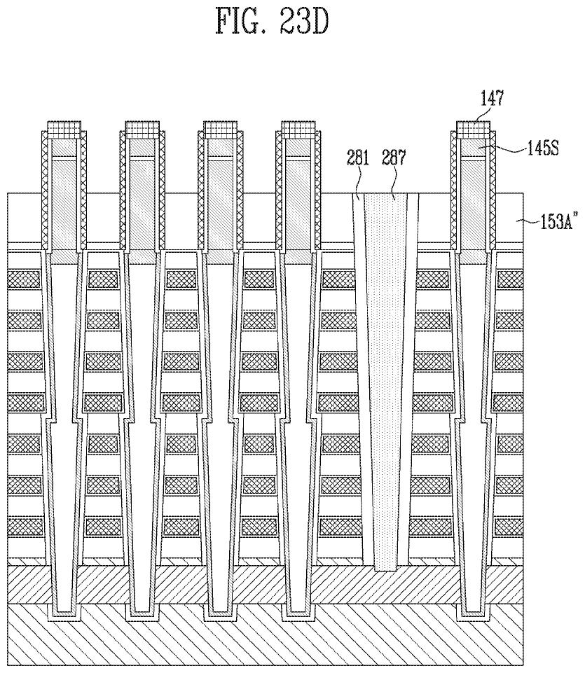

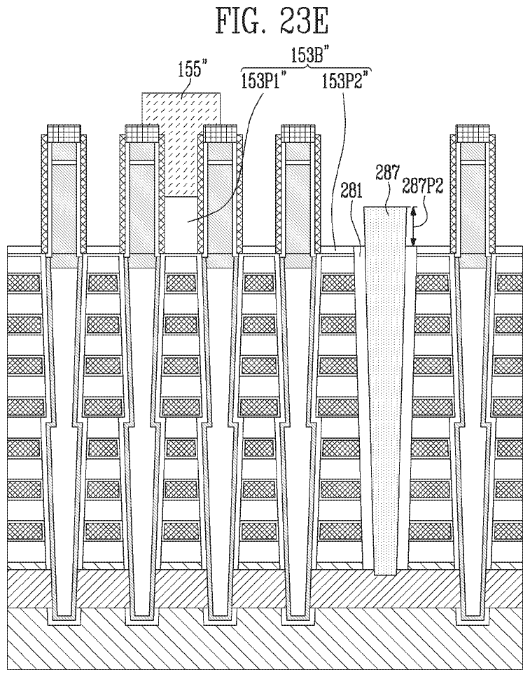

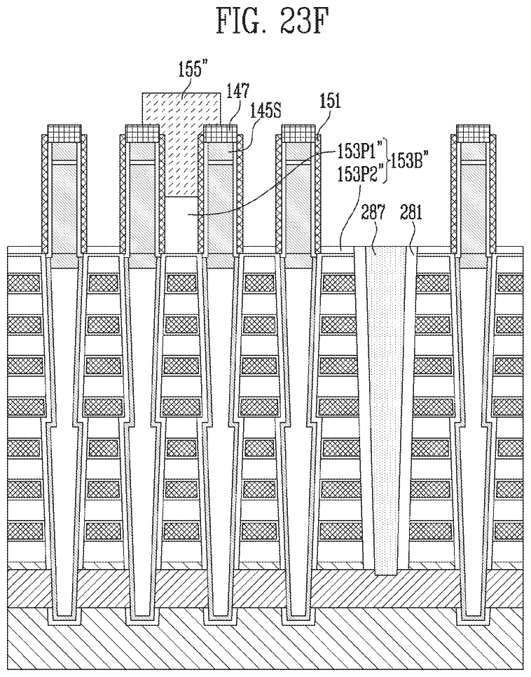

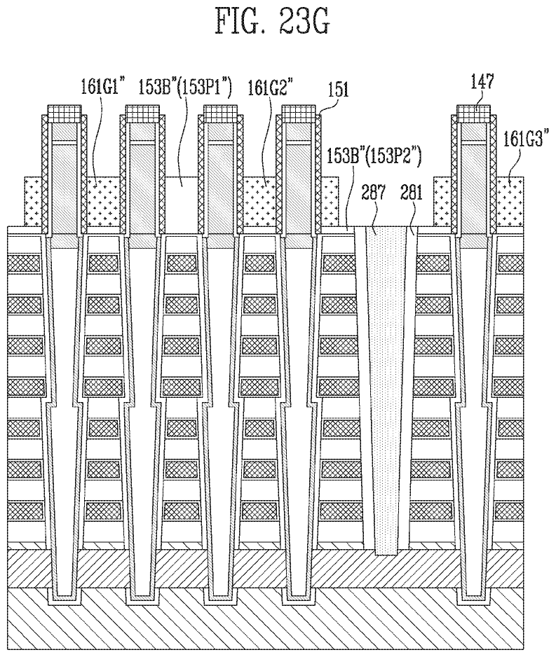

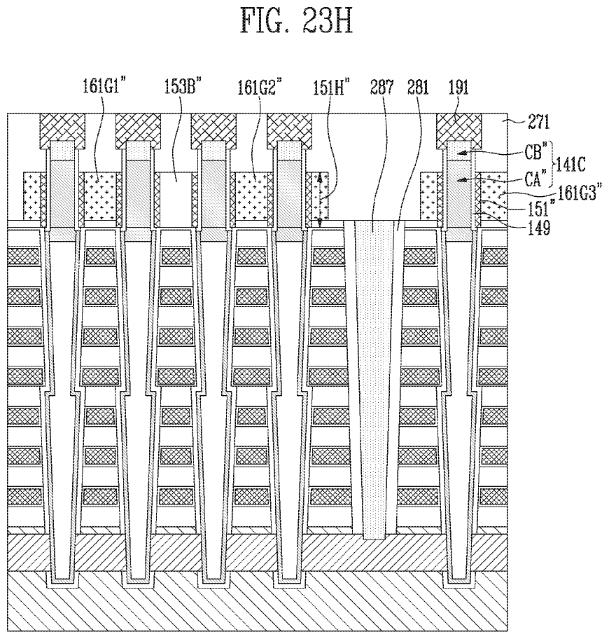

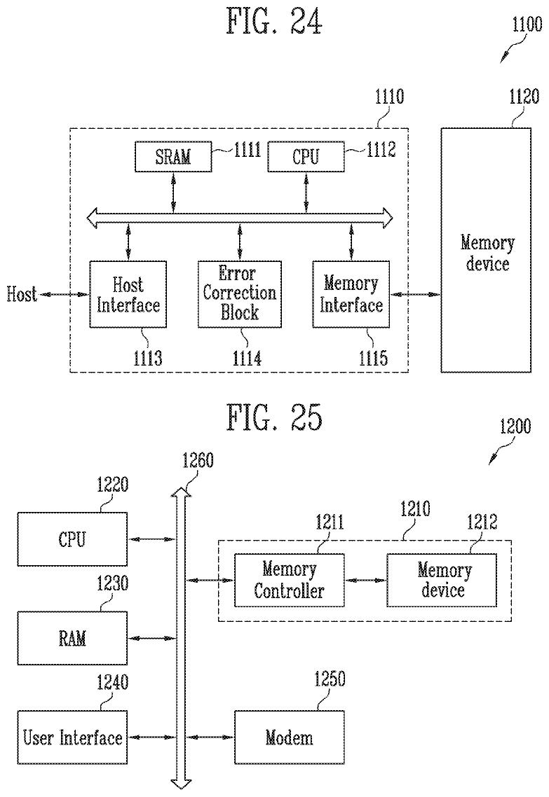

FIGS. 23A, 23B, 23C, 23D, 23E, 23F, 23G, and 23H are sectional views illustrating embodiments of subsequent processes to be performed after the process of FIG. 11D.

Referring to FIG. 23A, in the state in which the first mask pattern 147 and the first gate patterns 151 are covered with the insulating layer 153, a slit 273 may be formed. The slit 273 may pass through the insulating layer 153 and the stacked body 110. The memory layer 121 between the insulating layer 153 and the stacked body 110 may be penetrated by the slit 273.

The slit 273 may pass through the preliminary source layer 109 and the second source protective layer 107 of the preliminary source structure 100. A bottom surface of the slit 273 may be defined along the surface of the sacrificial source layer 105.

Referring to FIG. 23B, a replace process may be performed through the slit 273 illustrated in FIG. 23A. The replace process may include the step of replacing each of the second material layers 113, illustrated in FIG. 23A, with a blocking insulating layer 177″ and a conductive pattern 179″ and the step of replacing the first source protective layer 103, the sacrificial source layer 105, and the second source protective layer 107, which are illustrated in FIG. 23A, with a channel contact layer 185″.

The blocking insulating layer 177″ and the conductive pattern 179″ may be formed using the processes described above with reference to FIGS. 20B and 20C.

Before the channel contact layer 185″ is formed, a sidewall insulating layer 281 which covers the first material layers 111 and the sidewall of the conductive pattern 179″ may be formed.

The channel contact layer 185″ may be formed using the processes described above with reference to FIGS. 20D and 20E. The channel contact layer 185″ may come into contact with the first doped semiconductor layer 101 and the preliminary source layer 109 of FIG. 23A. Conductive dopants may be diffused from the channel contact layer 185″ to the preliminary source layer 109 of FIG. 23A. In this way, a second doped semiconductor layer 109S″ may be defined.

The channel contact layer 185″ may be disposed between the first doped semiconductor layer 101 and the second doped semiconductor layer 109S″, and may come into contact with the sidewall of the channel layer 123. The memory layer 121 illustrated in FIG. 23A may be separated into a first memory layer 121A″ and a second memory layer 121B″ through the channel contact layer 185″.

After the channel contact layer 185″ has been formed, a vertical source contact 287, which fills the slit 273 illustrated in FIG. 23A, may be formed. The vertical source contact 287 may extend to a level at which the top surface of the insulating layer 153 is disposed. The vertical source contact 287 may include doped silicon.

Referring to FIG. 23C, a portion of the insulating layer 153 illustrated in FIG. 23B may be etched, and thus the thickness of the insulating layer 153 may be reduced. An insulating layer 153A″, remaining after the etching process, may have a top surface 153TS″ disposed at a level lower than that of the top surface 141TS of each of the upper channel portions 141C.

While the portion of the insulating layer is etched, a portion of the sidewall insulating layer 281 may be etched. Accordingly, a first protrusion 287P1 of the vertical source contact 287, which protrudes upwardly higher than the sidewall insulating layer 281 and the insulating layer 153A″, may be defined.

Referring to FIG. 23D, the first protrusion 287P1 illustrated in FIG. 23C may be selectively removed through an etch-back process. While the first protrusion 287P1 illustrated in FIG. 23C is removed, the sacrificial pattern 145S may be protected by the first mask pattern 147.

Referring to FIG. 23E, as described above with reference to FIGS. 14 and 15, a second mask pattern 155″ may be formed on the insulating layer 153A″, illustrated in FIG. 23D. Thereafter, a portion of the insulating layer 153A″, illustrated in FIG. 23D, may be etched through an etching process that uses the second mask pattern 155″ as an etching barrier. In this way, a separation insulating pattern 153B″ may be defined. As described above with reference to FIGS. 14 and 15, the separation insulating pattern 153B″ may include a vertical portion 153P1″ and a horizontal portion 153P2″.

During the process for etching the insulating layer, a portion of the sidewall insulating layer 281 may be etched. Accordingly, a second protrusion 287P2 of the vertical source contact 287, which protrudes upwardly higher than the sidewall insulating layer 281 and the horizontal portion 153P2″ of the separation insulating layer 153B″, may be defined.

Referring to FIG. 23F, the second protrusion 287P2, illustrated in FIG. 23E, may be selectively removed through an etch-back process. While the second protrusion 287P2 illustrated in FIG. 23E is removed, the sacrificial pattern 145S may be protected by the first mask pattern 147.

Referring to FIG. 23G, the second mask pattern 155″ illustrated in FIG. 23F may be removed such that the vertical portion 153P1″ of the separation insulating pattern 153B″ is exposed.

Thereafter, second gate patterns 161G1″, 161G2″, and 161G3″ may be formed using the processes described above with reference to FIGS. 16 and 17A. The second gate patterns 161G1″, 161G2″, and 161G3″ may be disposed on the horizontal portion 153P2″ of the separation insulating pattern 153B″.

Referring to FIG. 23H, upper portions of the first gate patterns 151 illustrated in FIG. 23G may be etched. A gate length may be defined by the height 151H″ of first gate patterns 151″ remaining after etching.

Next, an upper insulating layer 271 may be formed. The upper insulating layer 271 may cover the sidewall insulating layer 281, the vertical source contact 287, the gate insulating layers 149, the first gate patterns 151″, the separation insulating pattern 153B″, the second gate patterns 161G1″, 161G2″, and 161G3″, and the first mask pattern 147 of FIG. 23G.

Thereafter, the surface of the upper insulating layer 271 may be planarized such that the first mask pattern 147 of FIG. 23G is exposed. Thereafter, the concentrations of conductive impurities included in a first area CA″ and a second area CB″ of the upper channel portion 141C may be formed to be different from each other using the processes described above with reference to FIGS. 21A to 21C. In an embodiment, the second area CB″ may be defined as a doped area including conductive impurities. The first area CA″ may be defined as an area formed of a substantially intrinsic semiconductor material.

Thereafter, a conductive contact 191″ coming into contract with the second area CB″ of the upper channel portion 141C may be formed using the processes described above with reference to FIGS. 21D and 21E.

The semiconductor memory device, described above with reference to FIG. 6, may be provided using the processes described above with reference to FIGS. 23A, 23B, 23C, 23D, 23E, 23F, 23G, and 23H.

In accordance with embodiments of the present disclosure, a separation insulating pattern may be stably disposed between a first gate pattern in a first row and a first gate pattern in a second row. In accordance with embodiments of the present disclosure, first gate patterns spaced apart from each other may be coupled to each other through a second gate pattern, and thus a drain select line may be defined. In accordance with embodiments of the present disclosure, process variation in the length of an upper channel portion of a channel structure enclosed by first gate patterns and process variation in the range of a dopant region in the channel structure may be reduced.

FIG. 24 is a block diagram illustrating the configuration of a memory system according to an embodiment of the present disclosure.

Referring to FIG. 24, a memory system 1100 includes a memory device 1120 and a memory controller 1110.

The memory device 1120 may be a multi-chip package composed of a plurality of flash memory chips. The memory device 1120 may include a lower channel portion enclosed by a memory layer, an upper channel portion on the lower channel portion, a gate insulating layer enclosing the upper channel portion, a first gate pattern enclosing the gate insulating layer, a separation insulating pattern disposed on one side of the first gate pattern, and a second gate pattern disposed on the other side of the first gate pattern. The first gate pattern may include a first sidewall contacting the separation insulating pattern and a second sidewall contacting the second gate pattern.

The memory controller 1110 may control the memory device 1120, and may include a static random access memory (SRAM) 1111, a central processing unit (CPU) 1112, a host interface 1113, an error correction block 1114, and a memory interface 1115. The SRAM 1111 may be used as a working memory of the CPU 1112, the CPU 1112 may perform overall control operations for data exchange of the memory controller 1110, and the host interface 1113 may be provided with a data interchange protocol of a host coupled to the memory system 1100. The error correction block 1114 may detect errors included in data read from the memory device 1120, and may correct the detected errors. The memory interface 1115 may interface with the memory device 1120. The memory controller 1110 may further include a read only memory (ROM) or the like that stores code data for interfacing with the host.

The above-described memory system 1100 may be a memory card or a solid state drive (SSD) in which the memory device 1120 and the memory controller 1110 are combined with each other. For example, when the memory system 1100 is an SSD, the memory controller 1110 may communicate with an external device (e.g., host) via one of various interface protocols, such as a universal serial bus (USB), a multimedia card (MMC), a peripheral component interconnection-express (PCI-E), a serial advanced technology attachment (SATA), a parallel advanced technology attachment (PATA), a small computer system interface (SCSI), an enhanced small disk interface (ESDI), or an Integrated Drive Electronics (IDE).

FIG. 25 is a block diagram illustrating the configuration of a computing system according to an embodiment of the present disclosure.

Referring to FIG. 25, a computing system 1200 may include a CPU 1220, a random access memory (RAM) 1230, a user interface 1240, a modem 1250, and a memory system 1210 which are electrically coupled to a system bus 1260. When the computing system 1200 is a mobile device, it may further include a battery for supplying an operating voltage to the computing system 1200, and may further include an application chipset, an image processor, a mobile DRAM, etc.

The memory system 1210 may include a memory device 1212 and a memory controller 1211.

The memory device 1212 may include a lower channel portion enclosed by a memory layer, a upper channel portion on the lower channel portion, a gate insulating layer enclosing the upper channel portion, a first gate pattern enclosing the gate insulating layer, a separation insulating pattern disposed on one side of the first gate pattern, and a second gate pattern disposed on the other side of the first gate pattern. The first gate pattern may include a first sidewall contacting the separation insulating pattern and a second sidewall contacting the second gate pattern.

The memory controller 1211 may be implemented in the same manner as the memory controller 1110, described above with reference to FIG. 24.

The present disclosure may improve the operational reliability of a semiconductor memory device by reducing process variation.

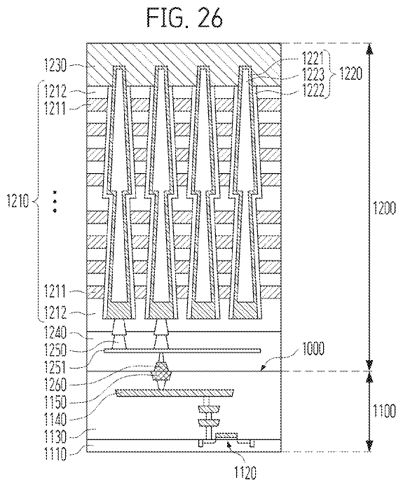

FIG. 26 is a diagram illustrating the structure of a semiconductor device in accordance with an embodiment.

Referring to FIG. 26, the semiconductor device may include a first semiconductor structure 1100 and a second semiconductor structure 1200. A bonding interface 1000 may be located in the semiconductor device, and the first semiconductor structure 1100 is distinguished from the second semiconductor structure 1200 by the bonding interface 1000. The second semiconductor structure 1200 may be disposed over or under the first semiconductor structure 1100. The first semiconductor structure 1100 may include a peripheral circuit, and the second semiconductor structure 1200 may include a memory cell array.

The first semiconductor structure 1100 may include a substrate 1110, a transistor 1120, a first interlayer insulating layer 1130, a first interconnection structure 1140, and a first bonding pad 1150. The transistor 1120 may be included in the peripheral circuit. The peripheral circuit may include a row decoder, a page buffer, an input/output circuit, a logic circuit, and the like. The first interconnection structure 1140 may be disposed in the first interlayer insulating layer 1130 and may include a via, a wiring line, and the like. The first bonding pad 1150 may be disposed at the bonding interface 1000 and may be electrically connected to the peripheral circuit through the first interconnection structure 1140.

The second semiconductor structure 1200 may include a gate structure 1210, a channel structure 1220, a source structure 1230, a second interlayer insulating layer 1240, a second interconnection structure 1250, and a second bonding pad 1260. The gate structure 1210 may include gate lines 1211 alternately stacked with insulating layers 1212. The source structure 1230 may be disposed over the gate structure 1210. The channel structure 1220 may include a channel layer 1221, a memory layer 1222, and/or an insulating core 1223. The channel layer 1221 may extend through the gate structure 1210 and may be connected to the source structure 1230. The second interconnection structure 1250 may be disposed in the second interlayer insulating layer 1240 and may include a via, a wiring line, and the like. For example, the second interconnection structure 1250 may include a bitline 1251. The second bonding pad 1260 may be disposed at the bonding interface 1000 and may be electrically connected to the memory cell array through the second interconnection structure 1250.

The first bonding pad 1150 may be electrically connected to the second bonding pad 1260 at the bonding interface 1000, and the memory cell array may be electrically connected to the peripheral circuit through the first bonding pad 1150 and the second bonding pad 1260.

The semiconductor device may be manufactured using a method such as hybrid bonding, metal bonding, insulator bonding, or semiconductor bonding. For example, the semiconductor device may be manufactured by manufacturing a first wafer including the peripheral circuit and a second wafer including the memory cell array, and bonding the first wafer to the second wafer.

Some of the first semiconductor structure 1100 and the second semiconductor structure 1200 may be formed after the first wafer is bonded to the second wafer. For example, the second wafer including a substrate, the gate structure 1210, and the channel structure 1220 may be formed, flipped, and bonded to the first wafer including the transistor 1120. Subsequently, a rear surface of the gate structure 1210 may be exposed by removing the substrate of the second wafer, and the channel layer 1221 may be exposed by etching the memory layer 1222 of the channel structure 1220 protruding from the rear surface of the gate structure 1210. The source structure 1230 may be formed on the rear surface of the gate structure 1210.

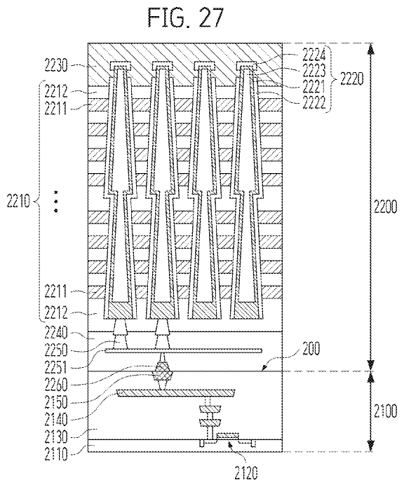

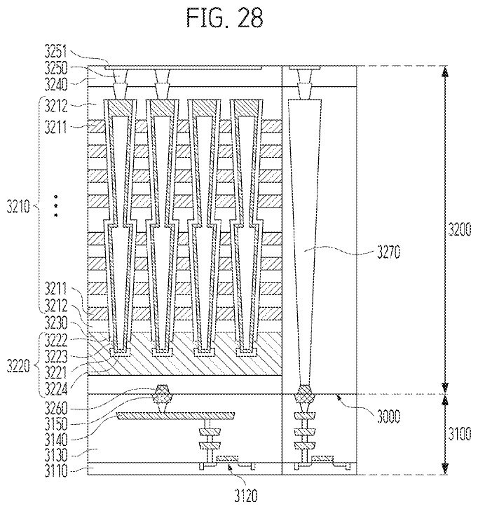

FIG. 27 is a diagram illustrating the structure of a semiconductor device in accordance with an embodiment.

Referring to FIG. 27, the semiconductor device may include a first semiconductor structure 2100 and a second semiconductor structure 2200. A bonding interface 2000 may be located in the semiconductor device, and the first semiconductor structure 2100 may be distinguished from the second semiconductor structure 2200 by the bonding interface 2000. The second semiconductor structure 2200 may be disposed over or under the first semiconductor structure 2100. The first semiconductor structure 2100 may include a peripheral circuit, and the second semiconductor structure 2200 may include a memory cell array.

The first semiconductor structure 2100 may include a substrate 2110, a transistor 2120, a first interlayer insulating layer 2130, a first interconnection structure 2140, and a first bonding pad 2150. The transistor 2120 may be included in the peripheral circuit. The peripheral circuit may include a row decoder, a page buffer, an input/output circuit, a logic circuit, and the like. The first interconnection structure 2140 may be disposed in the first interlayer insulating layer 2130 and may include a via, a wiring line, and the like. The first bonding pad 2150 may be disposed at the bonding interface 2000 and may be electrically connected to the peripheral circuit through the first interconnection structure 2140.

The second semiconductor structure 2200 may include a gate structure 2210, a channel structure 2220, a source structure 2230, a second interlayer insulating layer 2240, a second interconnection structure 2250, and a second bonding pad 2260. The gate structure 2210 may include gate lines 2211 alternately stacked with insulating layers 2212. The source structure 2230 may be disposed over the gate structure 2210. The channel structure 2220 may include a channel layer 2221, a memory layer 2222, an insulating core 2223, and/or a memory pattern 2224. The channel layer 2221 may extend through the gate structure 2210 and may be connected to the source structure 2230. The second interconnection structure 2250 may be disposed in the second interlayer insulating layer 2240 and may include a via, a wiring line, and the like. For example, the second interconnection structure 2250 may include a bitline 2251. The second bonding pad 2260 may be disposed at the bonding interface 2000 and may be electrically connected to the memory cell array through the second interconnection structure 2250.

The first bonding pad 2150 may be electrically connected to the second bonding pad 2260 at the bonding interface 2000, and the memory cell array may be electrically connected to the peripheral circuit through the first bonding pad 2150 and the second bonding pad 2260.

The semiconductor device may be manufactured using a method such as hybrid bonding, metal bonding, insulator bonding, or semiconductor bonding. For example, the semiconductor device may be manufactured by manufacturing a first wafer including the peripheral circuit and a second wafer including the memory cell array, and bonding the first wafer to the second wafer.

When the second wafer is manufactured, the source structure 2230 may be connected to the channel layer 2221 using a source sacrificial layer. For example, the channel structure 2220 may be formed to protrude into a source structure including the source sacrificial layer. An opening exposing the channel structure 2220 may be formed by removing the source sacrificial layer, and the channel layer 2221 may be exposed by etching the memory layer 2222 through the opening. A source layer connected to the channel layer 2221 may be formed in the opening to form the source structure 2230 including the source layer. The second wafer including the source structure 2230 may be flipped and bonded to the first wafer including the transistor 2120.

FIG. 28 is a diagram illustrating the structure of a semiconductor device in accordance with an embodiment.

Referring to FIG. 28, the semiconductor device may include a first semiconductor structure 3100 and a second semiconductor structure 3200. A bonding interface 3000 may be located in the semiconductor device, and the first semiconductor structure 3100 may be distinguished from the second semiconductor structure 3200 by the bonding interface 3000. The second semiconductor structure 3200 may be disposed over or under the first semiconductor structure 3100. The first semiconductor structure 3100 may include a peripheral circuit, and the second semiconductor structure 3200 may include a memory cell array.

The first semiconductor structure 3100 may include a substrate 3110, a transistor 3120, a first interlayer insulating layer 3130, a first interconnection structure 3140, and a first bonding pad 3150. The transistor 3120 may be included in the peripheral circuit. The peripheral circuit may include a row decoder, a page buffer, an input/output circuit, a logic circuit, and the like. The first interconnection structure 3140 may be disposed in the first interlayer insulating layer 3130 and may include a via, a wiring line, and the like. The first bonding pad 3150 may be disposed at the bonding interface 3000 and may be electrically connected to the peripheral circuit through the first interconnection structure 3140.

The second semiconductor structure 3200 may include a gate structure 3210, a channel structure 3220, a source structure 3230, a second interlayer insulating layer 3240, a second interconnection structure 3250, a second bonding pad 3260, and a contact plug 3270. The gate structure 3210 may include gate lines 3211 alternately stacked with insulating layers 3212. The source structure 3230 may be disposed below the gate structure 3210. The channel structure 3220 may include a channel layer 3221, a memory layer 3222, an insulating core 3223, and/or a memory pattern 3224. The channel layer 3221 may extend through the gate structure 3210, and may be connected to the source structure 3230. The second interconnection structure 3250 may be disposed in the second interlayer insulating layer 3240 and may include a via, a wiring line, and the like. For example, the second interconnection structure 3250 may include a bitline 3251. The second bonding pad 3260 may be disposed at the bonding interface 3000 and may be electrically connected to the memory cell array through the second interconnection structure 3250.

The first bonding pad 3150 may be electrically connected to the second bonding pad 3260 at the bonding interface 3000, and the memory cell array may be electrically connected to the peripheral circuit through the first bonding pad 3150 and the second bonding pad 3260. The contact plug 3270 may extend through the second interlayer insulating layer 3240 or a dummy stack and may be connected to the peripheral circuit through the first bonding pad 3150 and the second bonding pad 3260.

The semiconductor device may be manufactured using a method such as hybrid bonding, metal bonding, insulator bonding, or semiconductor bonding. For example, the semiconductor device may be manufactured by manufacturing a first wafer including the peripheral circuit and a second wafer including the memory cell array, and bonding the first wafer to the second wafer.

When the second wafer is manufactured, the source structure 3230 may be connected to the channel layer 3221 using a source sacrificial layer. For example, the channel structure 3220 protrudes into a source structure including the source sacrificial layer. Subsequently, an opening exposing the channel structure 3220 may be formed by removing the source sacrificial layer, and the channel layer 3221 may be exposed by etching the memory layer 3222 through the opening. A source layer connected to the channel layer 3221 may be formed in the opening to form the source structure 3230 including the source layer. The second wafer including the source structure 3230 may be bonded to the first wafer including the transistor 3120. In this example, the second wafer may be bonded to the first wafer in an un-flipped state. An interconnection structure such as a through silicon via (TSV) may be formed.

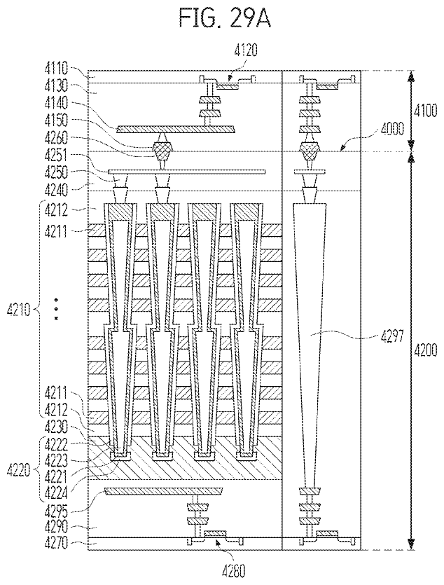

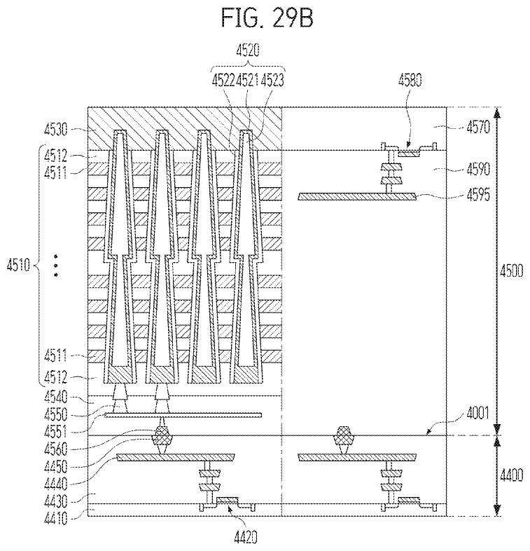

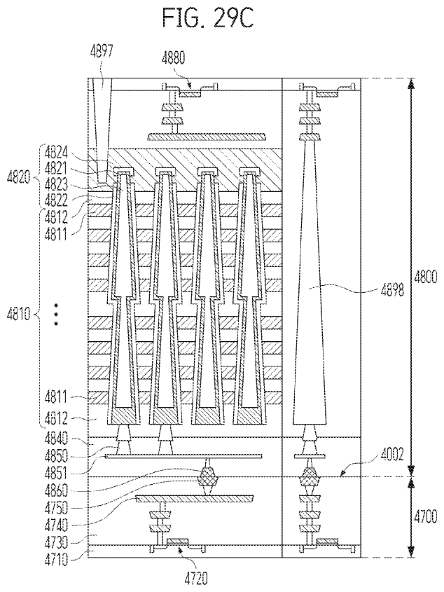

FIG. 29A is a diagram illustrating the structure of a semiconductor device in accordance with an embodiment.

Referring to FIG. 29A, the semiconductor device may include a first semiconductor structure 4100 and a second semiconductor structure 4200. A bonding interface 4000 may be located in the semiconductor device, and the first semiconductor structure 4100 may be distinguished from the second semiconductor structure 4200 by the bonding interface 4000. The second semiconductor structure 4200 may be disposed over or under the first semiconductor structure 4100. A peripheral circuit may include a first peripheral circuit and a second peripheral circuit. The first peripheral circuit and the second peripheral circuit may be distributed and disposed in the first semiconductor structure 4100 and the second semiconductor structure 4200. The first semiconductor structure 4100 may include the first peripheral circuit, and the second semiconductor structure 4200 may include the second peripheral circuit and a memory cell array.

The first semiconductor structure 4100 may include a first substrate 4110, a first transistor 4120, a first interlayer insulating layer 4130, a first interconnection structure 4140, and a first bonding pad 4150. The first transistor 4120 may be included in the first peripheral circuit. The first peripheral circuit may include a row decoder, a page buffer, an input/output circuit, a logic circuit, and the like. The first interconnection structure 4140 may be disposed in the first interlayer insulating layer 4130 and may include a via, a wiring line, and the like. The first bonding pad 4150 may be disposed at the bonding interface 4000 and may be electrically connected to the first peripheral circuit through the first interconnection structure 4140.

The second semiconductor structure 4200 may include a gate structure 4210, a channel structure 4220, a source structure 4230, a second interlayer insulating layer 4240, a second interconnection structure 4250, a second bonding pad 4260, a second substrate 4270, a second transistor 4280, a third interlayer insulating layer 4290, a third interconnection structure 4295, and a contact plug 4297.

The second transistor 4280 may be disposed on the second substrate 4270. The second transistor 4280 may be included in the second peripheral circuit. The second peripheral circuit may include a row decoder, a page buffer, an input/output circuit, a logic circuit, and the like. The third interconnection structure 4295 may be formed in the third interlayer insulating layer 4290 and may include a via, a wiring line, and the like. The third interconnection structure 4295 may be electrically connected to the second peripheral circuit.

The gate structure 4210 may be disposed over the second peripheral circuit. The gate structure 4210 may include gate lines 4211 alternately stacked with insulating layers 4212. The source structure 4230 may be disposed under the gate structure 4210. The channel structure 4220 may include a channel layer 4221, a memory layer 4222, an insulating core 4223, and/or a memory pattern 4224. The channel layer 4221 may extend through the gate structure 4210 and may be connected to the source structure 4230. The second interconnection structure 4250 may be disposed in the second interlayer insulating layer 4240 and may include a via, a wiring line, and the like. For example, the second interconnection structure 4250 may include a bitline 4251. The second bonding pad 4260 may be disposed at the bonding interface 4000 and may be electrically connected to the memory cell array through the second interconnection structure 4250.

The first bonding pad 4150 may be electrically connected to the second bonding pad 4260 at the bonding interface 4000, and the memory cell array may be electrically connected to the first peripheral circuit through the first bonding pad 4150 and the second bonding pad 4260. The contact plug 4297 may extend through the second interlayer insulating layer 4240 or a dummy stack. The first peripheral circuit may be connected to the second peripheral circuit through the contact plug 4297, the first bonding pad 4150 and the second bonding pad 4260.

The semiconductor device may be manufactured using a method such as hybrid bonding, metal bonding, insulator bonding, or semiconductor bonding. For example, the semiconductor device may be manufactured by manufacturing a first wafer including the first peripheral circuit and a second wafer including the second peripheral circuit and the memory cell array, and bonding the first wafer to the second wafer.

When the second wafer is manufactured, the source structure 4230 may be connected to the channel layer 4221 using a source sacrificial layer. For example, the second peripheral circuit may be formed on the second substrate 4270, and a source structure including the source sacrificial layer and the channel structure 4220 protruding into the source structure may be formed over the second peripheral circuit. An opening exposing the channel structure 4220 may be formed by removing the source sacrificial layer, and the channel layer 4221 may be exposed by etching the memory layer 4222 through the opening. A source layer connected to the channel layer 4221 may be formed in the opening to form the source structure 4230 including the source layer. The second wafer including the second peripheral circuit and the source structure 4230 may be bonded to the first wafer including the first peripheral circuit.

FIG. 29B is a diagram illustrating the structure of a semiconductor device in accordance with an embodiment.

Referring to FIG. 29B, the semiconductor device may include a first semiconductor structure 4400 and a second semiconductor structure 4500. A bonding interface 4001 may be located in the semiconductor device, and the first semiconductor structure 4400 may be distinguished from the second semiconductor structure 4500 by the bonding interface 4001. The second semiconductor structure 4500 may be disposed over or under the first semiconductor structure 4400. A peripheral circuit may include a first peripheral circuit and a second peripheral circuit. The first peripheral circuit and the second peripheral circuit may be distributed and disposed in the first semiconductor structure 4400 and the second semiconductor structure 4500. The first semiconductor structure 4400 may include the first peripheral circuit, and the second semiconductor structure 4500 may include the second peripheral circuit and a memory cell array.

The first semiconductor structure 4400 may include a first substrate 4410, a first transistor 4420, a first interlayer insulating layer 4430, a first interconnection structure 4440, and a first bonding pad 4450. The first transistor 4420 may be included in the first peripheral circuit. The first peripheral circuit may include a row decoder, a page buffer, an input/output circuit, a logic circuit, and the like. The first interconnection structure 4440 may be disposed in the first interlayer insulating layer 4430 and may include a via, a wiring line, and the like. The first interconnection structure 4440 may be electrically connected to the first peripheral circuit.

The second semiconductor structure 4500 may include a gate structure 4510, a channel structure 4520, a source structure 4530, a second interlayer insulating layer 4540, a second interconnection structure 4550, a second bonding pad 4560, a second substrate 4570, a second transistor 4580, a third interlayer insulating layer 4590, and a third interconnection structure 4595.

The second transistor 4580 may be disposed on the second substrate 4570. The second transistor 4580 may be included in the second peripheral circuit. The third interconnection structure 4595 may be formed in the third interlayer insulating layer 4590 and may include a via, a wiring line, and the like. The third interconnection structure 4595 may be electrically connected to the second peripheral circuit.

The source structure 4530 may be disposed at a level corresponding to the second substrate 4570, and the gate structure 4510 may be disposed under the source structure 4530. The gate structure 4510 may include gate lines 4511 alternately stacked with insulating layers 4512. The channel structure 4520 may include a channel layer 4521, a memory layer 4522, and/or an insulating core 4523. The channel layer 4521 may extend through the gate structure 4510 and may be connected to the source structure 4530. The second interconnection structure 4550 may be disposed in the second interlayer insulating layer 4540 and may include a via, a wiring line, and the like. For example, the second interconnection structure 4550 may include a bitline 4551. The second bonding pad 4560 may be disposed at the bonding interface 4001, and may be electrically connected to the memory cell array through the second interconnection structure 4550.

The first bonding pad 4450 may be electrically connected to the second bonding pad 4560 at the bonding interface 4001, and the memory cell array may be electrically connected to the first peripheral circuit through the first bonding pad 4450 and the second bonding pad 4560.

The semiconductor device may be manufactured using a method such as hybrid bonding, metal bonding, insulator bonding, or semiconductor bonding. For example, the semiconductor device may be manufactured by manufacturing a first wafer including the first peripheral circuit and a second wafer including the second peripheral circuit and the memory cell array, and bonding the first wafer to the second wafer.

Some of the first semiconductor structure 4400 and the second semiconductor structure 4500 may be formed after the first wafer is bonded to the second wafer. For example, the second peripheral circuit may be formed in a peripheral region of the second substrate 4560, and the channel structure 4520 protruding into the second substrate 4570 may be formed in a cell region of the second substrate 4570. The second wafer including the second peripheral circuit and the source structure 4530 may be flipped and bonded to the first wafer including the first peripheral circuit. Subsequently, a rear surface of the gate structure 4510 may be exposed by removing the cell region of the second substrate 4570, and the channel layer 4521 may be exposed by etching the memory layer 4522 of the channel structure 4520 protruding from the rear surface of the gate structure 4510. The source structure 4530 may be formed on the rear surface of the gate structure 4510.

FIG. 29C is a diagram illustrating the structure of a semiconductor device in accordance with an embodiment.

Referring to FIG. 29C, the semiconductor device may include a first semiconductor structure 4700 and a second semiconductor structure 4800. A bonding interface 4002 may be located in the semiconductor device, and the first semiconductor structure 4700 may be distinguished from the second semiconductor structure 4800 by the bonding interface 4002. The second semiconductor structure 4800 may be disposed over or under the first semiconductor structure 4700. A peripheral circuit may include a first peripheral circuit and a second peripheral circuit. The first peripheral circuit and the second peripheral circuit may be distributed and disposed in the first semiconductor structure 4700 and the second semiconductor structure 4800. The first semiconductor structure 4700 may include the first peripheral circuit, and the second semiconductor structure 4800 may include the second peripheral circuit and a memory cell array.

The first semiconductor structure 4700 may include a first substrate 4710, a first transistor 4720, a first interlayer insulating layer 4730, a first interconnection structure 4740, and a first bonding pad 4750. The first transistor 4720 may be included in the first peripheral circuit. The first peripheral circuit may include a row decoder, a page buffer, an input/output circuit, a logic circuit, and the like. The first interconnection structure 4740 may be disposed in the first interlayer insulating layer 4730 and may include a via, a wiring line, and the like. The first bonding pad 4750 may be disposed at the bonding interface 4002 and may be electrically connected to the first peripheral circuit through the first interconnection structure 4740.

The second semiconductor structure 4800 may include a gate structure 4810, a channel structure 4820, a source structure 4830, a second interlayer insulating layer 4840, a second interconnection structure 4850, a second bonding pad 4860, a second substrate 4870, a second transistor 4880, a third interlayer insulating layer 4890, a third interconnection structure 4895, a through via 4897, and a contact plug 4898.

The second transistor 4880 may be disposed on the second substrate 4870. The second transistor 4880 may be included in the second peripheral circuit. The second peripheral circuit may include a row decoder, a page buffer, an input/output circuit, a logic circuit, and the like. The third interconnection structure 4895 may be formed in the third interlayer insulating layer 4890 and may include a via, a wiring line, and the like. The third interconnection structure 4895 may be electrically connected to the second peripheral circuit.

The source structure 4830 may be disposed under the second peripheral circuit. The through via 4897 may extend through the second substrate 4870 and the third interlayer insulating layer 4890 and may be connected to the source structure 4830. The gate structure 4810 may be disposed under the source structure 4830. The gate structure 4810 may include gate lines 4811 alternately stacked with insulating layers 4812. The channel structure 4820 may include a channel layer 4821, a memory layer 4822, an insulating core 4823, and/or a memory pattern 4824. The channel layer 4821 may extend through the gate structure 4810 and may be connected to the source structure 4830. The second interconnection structure 4850 may be disposed in the second interlayer insulating layer 4840 and may include a via, a wiring line, and the like. For example, the second interconnection structure 4850 may include a bitline 4851. The second bonding pad 4860 may be disposed at the bonding interface 4002 and may be electrically connected to the memory cell array through the second interconnection structure 4850.

The first bonding pad 4750 may be electrically connected to the second bonding pad 4860 at the bonding interface 4002, and the memory cell array may be electrically connected to the first peripheral circuit through the first bonding pad 4750 and the second bonding pad 4860. The contact plug 4898 may extend through the second interlayer insulating layer 4840 or a dummy stack. The first peripheral circuit may be connected to the second peripheral circuit through the contact plug 4898, the first bonding pad 4750 and the second bonding pad 4860.

The semiconductor device may be manufactured using a method such as hybrid bonding, metal bonding, insulator bonding, or semiconductor bonding. For example, the semiconductor device may be manufactured by manufacturing a first wafer including the first peripheral circuit and a second wafer including the second peripheral circuit and the memory cell array, and bonding the first wafer to the second wafer.

Some of the first semiconductor structure 4700 and the second semiconductor structure 4800 may be formed after the first wafer may be bonded to the second wafer. For example, the second wafer including the second substrate 4870, the second peripheral circuit, and a source structure including a source sacrificial layer may be formed. The second wafer may be flipped and bonded to the first wafer including the first peripheral circuit. Subsequently, a through hole extending through the second substrate 4870 and the third interlayer insulating layer 4890 to expose the source sacrificial layer may be formed, and an opening, through which the channel structure 4820 is exposed, may be formed by removing the source sacrificial layer through the through hole. The channel layer 4821 may be exposed by etching the memory layer 4822 through the opening, and a source layer connected to the channel layer 4821 may be formed in the opening to form the source structure 4830 including the source layer. The through via 4897 may be formed in the through hole.

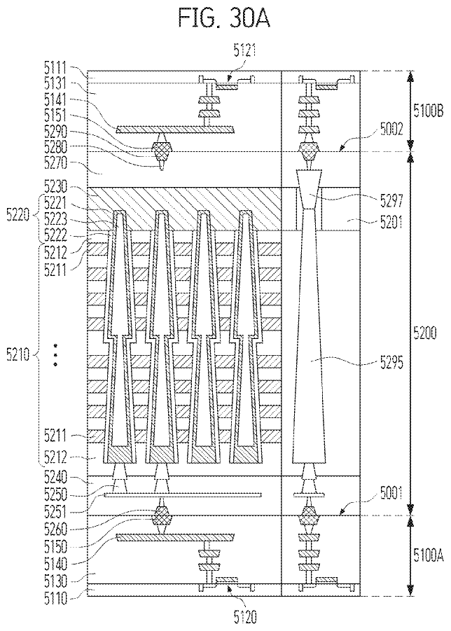

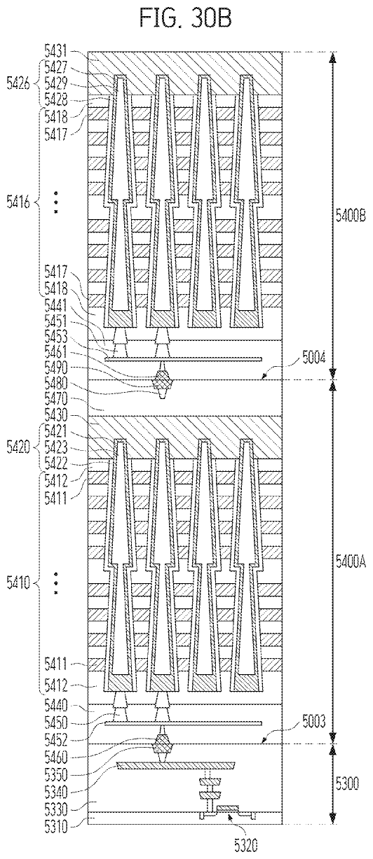

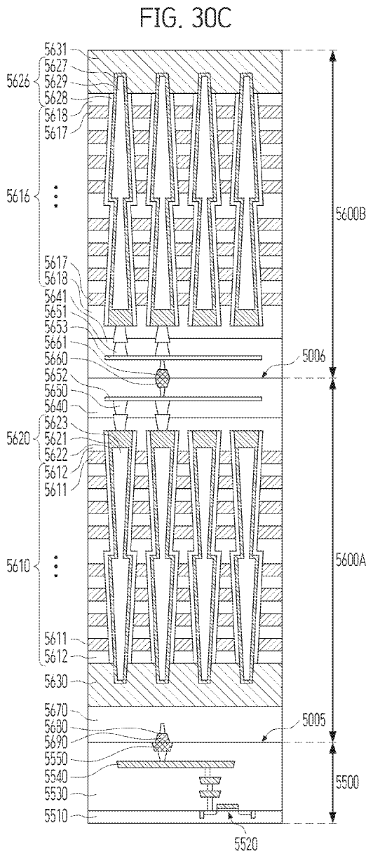

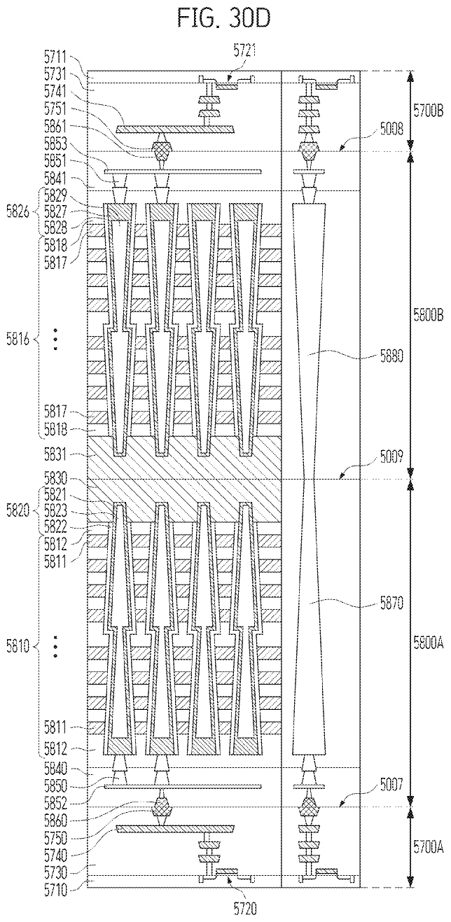

FIG. 30A is a diagram illustrating the structure of a semiconductor device in accordance with an embodiment.

Referring to FIG. 30A, the semiconductor device may include a first semiconductor structure 5100A, a second semiconductor structure 5100B, and a third semiconductor structure 5200. Bonding interfaces 5001 and 5002 may be located in the semiconductor device, and the first semiconductor structure 5100A, the second semiconductor structure 5100B, and the third semiconductor structure 5200 may be distinguished from each other by the bonding interfaces 5001 and 5002. The third semiconductor structure 5200 may be disposed between the first semiconductor structure 5100A and the second semiconductor structure 5100B. A peripheral circuit may include a first peripheral circuit and a second peripheral circuit. The first peripheral circuit and the second peripheral circuit may be distributed and disposed in the first semiconductor structure 5100A and the second semiconductor structure 5100B. The first semiconductor structure 5100A may include the first peripheral circuit, the second semiconductor structure 5100B may include the second peripheral circuit, and the third semiconductor structure 5200 may include a memory cell array.

The first semiconductor structure 5100A may include a first substrate 5110, a first transistor 5120, a first interlayer insulating layer 5130, a first interconnection structure 5140, and a first bonding pad 5150. The first transistor 5120 may be included in the first peripheral circuit. The first peripheral circuit may include a row decoder, a page buffer, an input/output circuit, a logic circuit, and the like. The first interconnection structure 5140 may be disposed in the first interlayer insulating layer 5130 and may include a via, a wiring line, and the like. The first bonding pad 5150 may be disposed at a first bonding interface 5001 and may be electrically connected to the first peripheral circuit through the first interconnection structure 5140.

The second semiconductor structure 5100B may include a second substrate 5111, a second transistor 5121, a second interlayer insulating layer 5131, a second interconnection structure 5141, and a second bonding pad 5151. The second transistor 5121 may be included in the second peripheral circuit. The second peripheral circuit may include a row decoder, a page buffer, an input/output circuit, a logic circuit, and the like. The second interconnection structure 5141 may be disposed in the second interlayer insulating layer 5131 and may include a via, a wiring line, and the like. The second bonding pad 5151 may be disposed at a second bonding interface 5002 and may be electrically connected to the second peripheral circuit through the second interconnection structure 5141.

The third semiconductor structure 5200 may include a substrate 5201, a gate structure 5210, a channel structure 5220, a source structure 5230, a third interlayer insulating layer 5240, a third interconnection structure 5250, a third bonding pad 5260, a fourth interlayer insulating layer 5270, a fourth interconnection structure 5280, a fourth bonding pad 5290, a first contact plug 5295, and a second contact plug 5297. The gate structure 5210 may include gate lines 5211 alternately stacked with insulating layers 5212. The source structure 5230 may be disposed over or under the gate structure 5210. The channel structure 5220 may include a channel layer 5221, a memory layer 5222, and/or an insulating core 5223. The channel layer 5221 may extend through the gate structure 5210 and may be connected to the source structure 5230. The third interconnection structure 5250 may be disposed in the third interlayer insulating layer 5240 and may include a via, a wiring line, and the like. For example, the third interconnection structure 5250 may include a bitline 5251. The fourth interconnection structure 5280 may be disposed in the fourth interlayer insulating layer 5270 and may include a via, a wiring line, and the like. The third bonding pad 5260 may be disposed at the first bonding interface 5001 and may be electrically connected to the memory cell array through the third interconnection structure 5250. The fourth bonding pad 5290 may be disposed at the second bonding interface 5002 and may be electrically connected to the memory cell array through the fourth interconnection structure 5280.

The first bonding pad 5150 may be electrically connected to the third bonding pad 5260 at the first bonding interface 5001, and the memory cell array may be electrically connected to the first peripheral circuit through the first bonding pad 5150 and the third bonding pad 5260. The second bonding pad 5151 may be electrically connected to the fourth bonding pad 5290 at the second bonding interface 5002, and the memory cell array may be electrically connected to the second peripheral circuit through the second bonding pad 5151 and the fourth bonding pad 5290.

The first contact plug 5295 may extend through the second interlayer insulating layer 5240 or a dummy stack, and the second contact plug 5297 may extend through the third substrate 5201. The first contact plug 5295 may be connected to the second contact plug 5297, and the first peripheral circuit may be connected to the second peripheral circuit through the first bonding pad 5150, the third bonding pad 5260, the first contact plug 5295, the second contact plug 5297, the fourth bonding pad 5290, and the second bonding pad 5151.

The semiconductor device may be manufactured using a method such as hybrid bonding, metal bonding, insulator bonding, or semiconductor bonding. The semiconductor device may be manufactured by manufacturing a first wafer including the first peripheral circuit, a second wafer including the second peripheral circuit, and a third wafer including the memory cell array, and bonding the first to third wafers together. For example, the third wafer may be flipped and bonded to the first wafer, and a substrate of the third wafer may be removed to form the source structure 5230. The second wafer may be flipped and bonded to the third wafer.

FIG. 30B is a diagram illustrating the structure of a semiconductor device in accordance with an embodiment.

Referring to FIG. 30B, the semiconductor device may include a first semiconductor structure 5300, a second semiconductor structure 5400A, and a third semiconductor structure 5400B. Bonding interfaces 5003 and 5004 may be located in the semiconductor device, and the first semiconductor structure 5300, the second semiconductor structure 5400A, and the third semiconductor structure 5400B may be distinguished by the bonding interfaces 5003 and 5004. The second semiconductor structure 5400A may be disposed between the first semiconductor structure 5300 and the third semiconductor structure 5400B. The first semiconductor structure 5300 may include a peripheral circuit, the second semiconductor structure 5400A may include a first memory cell array, and the third semiconductor structure 5400B may include a second memory cell array.

The first semiconductor structure 5300 may include a substrate 5310, a transistor 5320, a first interlayer insulating layer 5330, a first interconnection structure 5340, and a first bonding pad 5350. The transistor 5320 may be included in the peripheral circuit. The peripheral circuit may include a row decoder, a page buffer, an input/output circuit, a logic circuit, and the like. The first interconnection structure 5340 may be disposed in the first interlayer insulating layer 5330 and may include a via, a wiring line, and the like. The first bonding pad 5350 may be disposed at a first bonding interface 5003 and may be electrically connected to the peripheral circuit through the first interconnection structure 5340.

The second semiconductor structure 5400A may include a first gate structure 5410, a first channel structure 5420, a first source structure 5430, a second interlayer insulating layer 5440, a second interconnection structure 5450, a second bonding pad 5460, a third interlayer insulating layer 5470, a third interconnection structure 5480, and a third bonding pad 5490. The first gate structure 5410 may include first gate lines 5411 alternately stacked with first insulating layers 5412. The first source structure 5430 may be disposed over or under the first gate structure 5410. The first channel structure 5420 may include a first channel layer 5421, a first memory layer 5422, and/or a first insulating core 5423. The first channel layer 5421 may extend through the first gate structure 5410 and may be connected to the first source structure 5430. The second interconnection structure 5450 may be disposed in the second interlayer insulating layer 5440 and may include a via, a wiring line, and the like. For example, the second interconnection structure 5450 may include a bitline 5452. The third interconnection structure 5480 may be disposed in the third interlayer insulating layer 5470 and may include a via, a wiring line, and the like. The second bonding pad 5460 may be disposed at the first bonding interface 5003 and may be electrically connected to the first memory cell array through the second interconnection structure 5450. The third bonding pad 5490 may be disposed at a second bonding interface 5004, and may be electrically connected to the first memory cell array through the third interconnection structure 5480.

The third semiconductor structure 5400B may include a second gate structure 5416, a second channel structure 5426, a second source structure 5431, a fourth interlayer insulating layer 5441, a fourth interconnection structure 5451, and a fourth bonding pad 5461. The second gate structure 5416 may include second gate lines 5417 alternately stacked with second insulating layer 5418. The second source structure 5431 may be disposed over or under the second gate structure 5416. The second source structure 5431 may be electrically isolated from the first source structure 5430 and driven separately from the first source structure 5430 or may be electrically connected to the first source structure 5430 and driven in common with the first source structure 5430. The second channel structure 5426 may include a second channel layer 5427, a second memory layer 5428, and/or a second insulating core 5429. The second channel layer 5427 may extend through the second gate structure 5416 and may be connected to the second source structure 5431. The fourth interconnection structure 5451 may be disposed in the fourth interlayer insulating layer 5441 and may include a via, a wiring line, and the like. For example, the fourth interconnection structure 5451 may include a bitline 5453. The fourth bonding pad 5461 may be disposed at the second bonding interface 5004 and may be electrically connected to the second memory cell array through the fourth interconnection structure 5451.

The first bonding pad 5350 may be electrically connected to the second bonding pad 5460 at the first bonding interface 5003, and the first memory cell array may be electrically connected to the peripheral circuit through the first bonding pad 5350 and the second bonding pad 5460. The third bonding pad 5490 may be electrically connected to the fourth bonding pad 5461 at the second bonding interface 5004, and the second memory cell array may be electrically connected to the first memory cell array through the third bonding pad 5490 and the fourth bonding pad 5461.

The semiconductor device may be manufactured using a method such as hybrid bonding, metal bonding, insulator bonding, or semiconductor bonding. The semiconductor device may be manufactured by manufacturing a first wafer including the peripheral circuit, a second wafer including the first memory cell array, and a third wafer including the second memory cell array, and bonding the first to third wafers together. For example, the second wafer may be flipped and bonded to the first wafer, and a substrate of the second wafer may be removed to form the first source structure 5430. The third wafer may be flipped and bonded to the second wafer, and a substrate of the third wafer may be removed to form the second source structure 5431.

FIG. 30C is a diagram illustrating the structure of a semiconductor device in accordance with an embodiment.

Referring to FIG. 30C, the semiconductor device may include a first semiconductor structure 5500, a second semiconductor structure 5600A, and a third semiconductor structure 5600B. Bonding interfaces 5005 and 5006 may be located in the semiconductor device, and the first semiconductor structure 5500, the second semiconductor structure 5600A, and the third semiconductor structure 5600B may be distinguished by the bonding interfaces 5005 and 5006. The second semiconductor structure 5600A may be disposed between the first semiconductor structure 5500 and the third semiconductor structure 5600B. The first semiconductor structure 5500 may include a peripheral circuit, the second semiconductor structure 5600A may include a first memory cell array, and the third semiconductor structure 5600B may include a second memory cell array.

The first semiconductor structure 5500 may include a substrate 5510, a transistor 5520, a first interlayer insulating layer 5530, a first interconnection structure 5540, and a first bonding pad 5550. The transistor 5520 may be included in the peripheral circuit. The peripheral circuit may include a row decoder, a page buffer, an input/output circuit, a logic circuit, and the like. The first interconnection structure 5540 may be disposed in the first interlayer insulating layer 5530 and may include a via, a wiring line, and the like. The first bonding pad 5550 may be disposed at a first bonding interface 5005 and may be electrically connected to the peripheral circuit through the first interconnection structure 5540.

The second semiconductor structure 5600A may include a first gate structure 5610, a first channel structure 5620, a first source structure 5630, a second interlayer insulating layer 5640, a second interconnection structure 5650, a second bonding pad 5660, a third interlayer insulating layer 5670, a third interconnection structure 5680, and a third bonding pad 5690. The first gate structure 5610 may include first gate lines 5611 alternately stacked with first insulating layers 5612. The first source structure 5630 may be disposed over or under the first gate structure 5610. The first channel structure 5620 may include a first channel layer 5621, a first memory layer 5622, and/or a first insulating core 5623. The first channel layer 5621 may extend through the first gate structure 5610 and may be connected to the first source structure 5630. The second interconnection structure 5650 may be disposed in the second interlayer insulating layer 5640 and may include a via, a wiring line, and the like. For example, the second interconnection structure 5650 may include a bitline 5652. The third interconnection structure 5680 may be disposed in the third interlayer insulating layer 5670 and may include a via, a wiring line, and the like. The second bonding pad 5660 may be disposed at a second bonding interface 5006 and may be electrically connected to the first memory cell array through the second interconnection structure 5650. The third bonding pad 5690 may be disposed at the first bonding interface 5005 and may be electrically connected to the first memory cell array through the third interconnection structure 5680.

The third semiconductor structure 5600B may include a second gate structure 5616, a second channel structure 5626, a second source structure 5631, a fourth interlayer insulating layer 5641, a fourth interconnection structure 5651, and a fourth bonding pad 5661. The second gate structure 5616 may include second gate lines 5617 alternately stacked with second insulating layer 5618. The second source structure 5631 may be disposed over or under the second gate structure 5616. The second source structure 5631 may be electrically isolated from the first source structure 5630 and driven separately from the first source structure 5630 or may be electrically connected to the first source structure 5630 and driven in common with the first source structure 5630. The second channel structure 5626 may include a second channel layer 5627, a second memory layer 5628, and/or a second insulating core 5629. The second channel layer 5627 may extend through the second gate structure 5616 and may be connected to the second source structure 5631. The fourth interconnection structure 5651 may be disposed in the fourth interlayer insulating layer 5641 and may include a via, a wiring line, and the like. For example, the fourth interconnection structure 5651 may include a bitline 5653. The fourth bonding pad 5661 may be disposed at the second bonding interface 5006 and may be electrically connected to the second memory cell array through the fourth interconnection structure 5651.

The first bonding pad 5550 may be electrically connected to the third bonding pad 5690 at the first bonding interface 5005, and the first memory cell array may be electrically connected to the peripheral circuit through the first bonding pad 5550 and the third bonding pad 5690. The second bonding pad 5660 may be electrically connected to the fourth bonding pad 5661 at the second bonding interface 5006, and the second memory cell array may be electrically connected to the first memory cell array through the second bonding pad 5660 and the fourth bonding pad 5661.

The semiconductor device may be manufactured using a method such as hybrid bonding, metal bonding, insulator bonding, or semiconductor bonding. The semiconductor device may be manufactured by manufacturing a first wafer including the peripheral circuit, a second wafer including the first memory cell array, and a third wafer including the second memory cell array, and bonding the first to third wafers together. For example, the second wafer may be flipped and bonded to the third wafer, and a substrate of the second wafer may be removed to form the first source structure 5630. The second wafer and the first wafer may be bonded, and a substrate of the third wafer may be removed to form the second source structure 5631.

FIG. 30D is a diagram illustrating the structure of a semiconductor device in accordance with an embodiment.

Referring to FIG. 30D, the semiconductor device may include a first semiconductor structure 5700A, a second semiconductor structure 5700B, a third semiconductor structure 5800A, and a fourth semiconductor structure 5800B. Bonding interfaces 5007, 5008, and 5009 may be located in the semiconductor device, and the first semiconductor structure 5700A, the second semiconductor structure 5700B, the third semiconductor structure 5800A, and the fourth semiconductor structure 5800B may be distinguished by the bonding interfaces 5007, 5008, and 5009. The third semiconductor structure 5800A and the fourth semiconductor structure 5800B may be disposed between the first semiconductor structure 5700A and the second semiconductor structure 5700B. The first semiconductor structure 5700A may include a first peripheral circuit, the second semiconductor structure 5700B may include a second peripheral circuit, the third semiconductor structure 5800A may include a first memory cell array, and the fourth semiconductor structure 5800B may include a second memory cell array.

The first semiconductor structure 5700A may include a first substrate 5710, a first transistor 5720, a first interlayer insulating layer 5730, a first interconnection structure 5740, and a first bonding pad 5750. The first transistor 5720 may be included in the first peripheral circuit. The first peripheral circuit may include a row decoder, a page buffer, an input/output circuit, a logic circuit, and the like. The first interconnection structure 5740 may be disposed in the first interlayer insulating layer 5730 and may include a via, a wiring line, and the like. The first bonding pad 5750 may be disposed at a first bonding interface 5007 and may be electrically connected to the first peripheral circuit through the first interconnection structure 5740.

The second semiconductor structure 5700B may include a second substrate 5711, a second transistor 5721, a second interlayer insulating layer 5731, a second interconnection structure 5741, and a second bonding pad 5751. The second transistor 5721 may be included in the second peripheral circuit. The second peripheral circuit may include a row decoder, a page buffer, an input/output circuit, a logic circuit, and the like. The second interconnection structure 5741 may be disposed in the second interlayer insulating layer 5731 and may include a via, a wiring line, and the like. The second bonding pad 5751 may be disposed at a second bonding interface 5008 and may be electrically connected to the second peripheral circuit through the second interconnection structure 5741.

The third semiconductor structure 5800A may include a first gate structure 5810, a first channel structure 5820, a first source structure 5830, a third interlayer insulating layer 5840, a third interconnection structure 5850, a third bonding pad 5860, and a first contact plug 5870. The first gate structure 5810 may include first gate lines 5811 alternately stacked with first insulating layers 5812. The first source structure 5830 may be disposed over or under the first gate structure 5810. The first channel structure 5820 may include a first channel layer 5821, a first memory layer 5822, and/or a first insulating core 5823. The first channel layer 5821 may extend through the first gate structure 5810 and may be connected to the first source structure 5830. The third interconnection structure 5850 may be disposed in the third interlayer insulating layer 5840 and may include a via, a wiring line, and the like. For example, the third interconnection structure 5850 may include a bitline 5852. The third bonding pad 5860 may be disposed at the first bonding interface 5007 and may be electrically connected to the first memory cell array through the third interconnection structure 5850.

The fourth semiconductor structure 5800B may include a second gate structure 5816, a second channel structure 5826, a second source structure 5831, a fourth interlayer insulating layer 5841, a fourth interconnection structure 5851, a fourth bonding pad 5861, and a second contact plug 5880. The second gate structure 5816 may include second gate lines 5817 alternately stacked with second insulating layer 5818. The second source structure 5831 may be disposed over or under the second gate structure 5816. The second source structure 5831 may be electrically connected to the first source structure 5830 and driven in common with the first source structure 5830. The second channel structure 5826 may include a second channel layer 5827, a second memory layer 5828, and/or a second insulating core 5829. The second channel layer 5827 may extend through the second gate structure 5816 and may be connected to the second source structure 5831. The fourth interconnection structure 5851 may be disposed in the fourth interlayer insulating layer 5841 and may include a via, a wiring line, and the like. For example, the fourth interconnection structure 5851 may include a bitline 5853. The fourth bonding pad 5861 may be disposed at the second bonding interface 5008 and may be electrically connected to the second memory cell array through the fourth interconnection structure 5851.

The first bonding pad 5750 may be electrically connected to the third bonding pad 5860 at the first bonding interface 5007, and the first memory cell array may be electrically connected to the first peripheral circuit through the first bonding pad 5750 and the third bonding pad 5860. The second bonding pad 5751 may be electrically connected to the fourth bonding pad 5861 at the second bonding interface 5008, and the second memory cell array may be electrically connected to the second peripheral circuit through the second bonding pad 5751 and the fourth bonding pad 5861. The first source structure 5830 may be bonded to the second source structure 5831 at a third bonding interface 5009. Thus, the first memory cell array may be electrically connected to the second memory cell array.

The first contact plug 5870 may extend through the third interlayer insulating layer 5840 or a dummy stack, and the second contact plug 5880 may extend through the fourth interlayer insulating layer 5841 or a dummy stack. The first contact plug 5870 may be connected to the second contact plug 5880, and the first peripheral circuit may be connected to the second peripheral circuit through the first bonding pad 5750, the third bonding pad 5860, the first contact plug 5870, the second contact plug 5880, the fourth bonding pad 5861, and the second bonding pad 5751.

The semiconductor device may be manufactured using a method such as hybrid bonding, metal bonding, insulator bonding, or semiconductor bonding. The semiconductor device may be manufactured by manufacturing a first wafer including the first peripheral circuit, a second wafer including the first memory cell array, a third wafer including the second peripheral circuit, and a fourth wafer including the second memory cell array, and bonding the first to fourth wafers together. For example, the second wafer may be flipped and bonded to the first wafer, and a substrate of the second wafer may be removed to form the first source structure 5830. The fourth wafer may be flipped and bonded to the third wafer, and a substrate of the fourth wafer may be removed to form the second source structure 5831. The second wafer may be bonded to the fourth wafer.

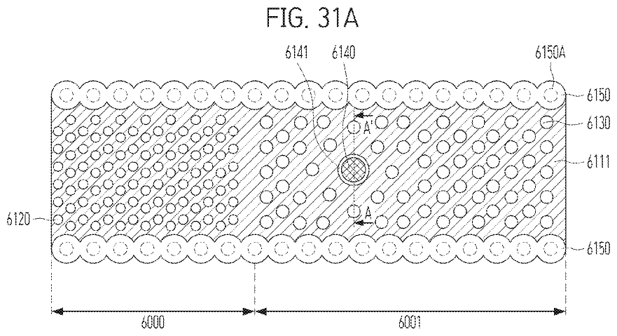

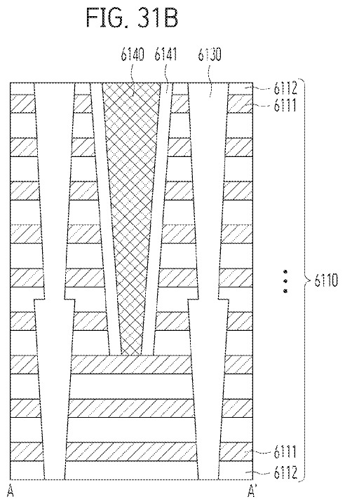

FIGS. 31A and 31B are diagrams illustrating the structure of a semiconductor device in accordance with an embodiment. FIG. 31B is a cross sectional view taken along line A A′ of FIG. 31A.

Referring to FIGS. 31A and 31B, the semiconductor device may include a gate structure 6110, channel structures 6120, supports 6130, a contact plug 6140, an insulating spacer 6141, and slit structures 6150. The term “slit structure” in the present disclosure does not indicate that a slit has a structure but rather is so named because the process of forming a slit structure utilizes a slit. The slit structures 6150 may extend in one direction, and the gate structure 6110 may be disposed between the slit structures 6150. Each of the slit structures 6150 may include an insulating material, a semiconductor material, and/or a conductive material. The gate structure 6110 may include gate lines 6111 alternately stacked with insulating layers 6112. The gate lines may be word lines, a source select line, or a drain select line.

The gate structure 6110 may include a cell region 6111 and a contact region 6112. The channel structures 6120 may be disposed in the cell region 6111 of the gate structure 6110. The channel structures 6120 may extend in a vertical direction through the gate structure 6110, and memory cells may be stacked along the channel structures 6120. The supports 6130 and the contact plug 6140 may be disposed in the contact region 6112 of the gate structure 6110. The supports 6130 may extend in the vertical direction through the gate structure 6110. Each of the supports 6130 may include an insulating material, a semiconductor material, and/or a conductive material.

The contact plug 6140 may be electrically connected to a gate line 6111. For example, the contact region 6112 of the gate structure 6110 may include a staircase structure (not shown), and the contact plug 6140 may be electrically connected to the gate line through the staircase structure. For example, the gate structure 6110 may not include the staircase structure, and the contact plug 6140 may extend through the gate structure 6110 and be electrically connected to the gate line. The insulating spacer 6141 may surround a sidewall of the contact plug 6140.

Processes of manufacturing the channel structures 6120, the supports 6130, and the slit structures 6150 may be performed simultaneously. Holes that form the channel structures 6120, the supports 6130, and the slit structures 6150 may be simultaneously formed, and sacrificial layers may be formed in the holes. The sacrificial layers are removed to form holes, and structures are formed within the holes. For example, holes 6150A arranged in a row may be formed in a region where the slit structure is to be formed. A slit may be formed by expanding the holes 6150A thereby connecting the holes 6150A together, and the slit structure 6150 may be formed in the slit. In such an example, the sidewalls of the slit structure 6150 may include irregularities or uneven surfaces.

The semiconductor device may be manufactured using a replacement process. For example, a stack may be formed including sacrificial layers alternately stacked with insulating layers, and a contact hole may be formed extending through the stack. A sacrificial pattern may be formed in the contact hole, and the sacrificial layers may be replaced with the gate lines 6111 to form the gate structure 6110. The sacrificial pattern may be removed, and the insulating spacer 6141 may be formed on sidewalls of the stack exposed by the contact hole. The contact plug 6140 may be formed within the insulating spacer 6141 formed in the contact hole.

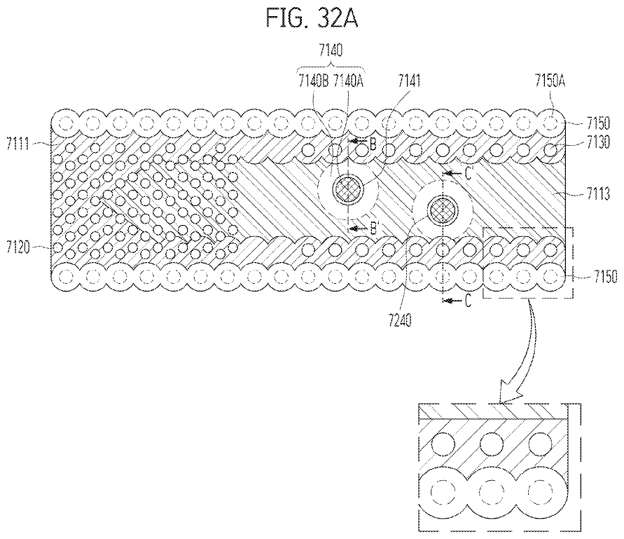

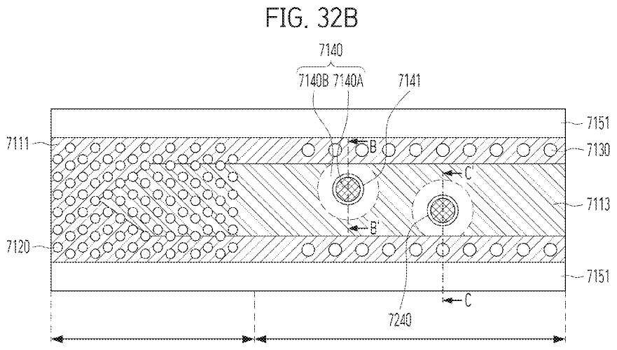

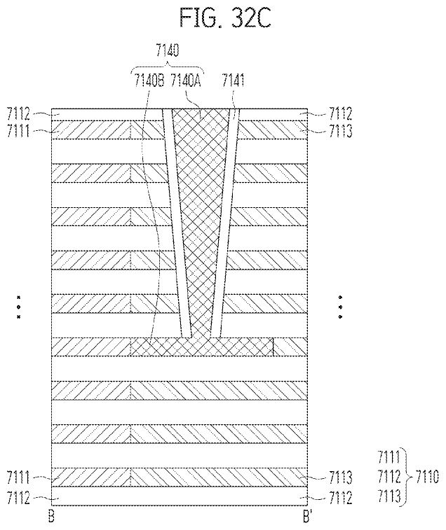

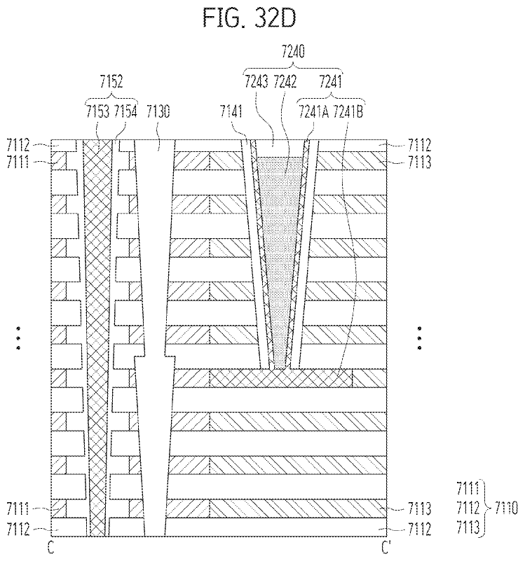

FIGS. 32A to 32D are a diagram illustrating the structure of a semiconductor device in accordance with an embodiment. FIG. 32C is a cross-sectional view taken along line B-B′ of FIG. 32A. FIG. 32D is a modified example of FIG. 32C and is a cross-sectional view taken along line C-C′ of FIG. 32A.

Referring to FIGS. 32A and 32B, the semiconductor device may include a gate structure 7110, channel structures 7120, supports 7130, a contact plug 7140, an insulating spacer 7141, and slit structures 7150 and 7151.

The slit structures 7150 may extend in one direction, and the gate structure 7110 may be disposed between the slit structures 7150. Referring to FIG. 32A, the slit structures 7150 may be formed within a slit defined by extending and connecting holes 7150A arranged in a row, and may have irregularities on their sidewalls. Referring to FIG. 32B, the slit structure 7151 may be formed within a line-shaped slit, and the sidewalls may have a linear shape without irregularities. Each of the slit structures 7150 and 7151 may include an insulating material, a semiconductor material, and/or a conductive material.

The gate structure 7110 may include gate lines 7111, insulating layers 7112, and dielectric layers 7113. The gate lines 7111 are alternately stacked with the insulating layers 7112, and the insulating layers 7112 may extend between the stacked dielectric layers 7113. The gate line 7111 may surround the dielectric layer 7113. The interface between the gate line 7111 and the dielectric layer 7113 may be uneven or corrugated, or may have a linear shape. The supports 7130 may be disposed between the dielectric layers 7113 and the slit structures 7150, and may extend through the gate lines 7111 and the insulating layers 7112.

The contact plug 7140 may include a pillar portion 7140A and a contact portion 7140B protruding from the pillar portion 7140A. The pillar portion 7140A and the contact portion 7140B may be formed as a single layer or may be formed as separate layers. The pillar portion 7140A may extend in the vertical direction through the insulating layers 7112 and the dielectric layers 7113. The contact portion 7140B may be disposed at a level corresponding to a dielectric layer 7113 and may extend in a horizontal direction to be electrically connected to the gate line 7111. The insulating spacer 7141 may surround the pillar portion 7140A. The semiconductor device may include a plurality of contact plugs 7140, and each of the plurality of contact plugs 7140 may extend to a different depth and be connected to a different gate line 7111. In an embodiment, the pillar 7120A and the contact 7120B are formed as a single unified structure, for example, formed in one process using the same material. Alternatively, the pillar 7120A and the contact 7120B may be formed separately and connected together.

Referring to FIGS. 32A and 32D, the semiconductor device may include a gate structure 7110, channel structures 7120, a contact plug 7240, an insulating spacer 7141, supports 7130, and a slit structure 7150. The gate structure 7110 may include gate lines 7111, insulating layers 7112, and dielectric layers 7113. The gate lines 7111 are alternately stacked with the insulating layers 7112, and the insulating layers 7112 may extend between the stacked dielectric layers 7113.

The supports 7130 may extend through the gate lines 7111 that are alternately stacked with the insulating layers 7112. The supports 7130 may each include an insulating material, a semiconductor material, and/or a conductive material. The slit structure 7150 may include a structure formed in a slit used as a passage for a replacement process and may extend between adjacent gate structures 7110. For example, the slit structure 7150 may include a conductive layer 7151 and an insulating spacer 7152 surrounding sidewalls of the conductive layer 7151. The insulating spacer 7152 may include protrusions protruding toward the gate lines 7111.

The contact plug 7240 may include a barrier layer 7241, a gap-fill insulating layer 7242, and a contact pad 7243. The gap-fill insulating layer 7242 may extend in the vertical direction through the dielectric layers 7113 and the insulating layers 7112. The contact pad 7243 may be disposed over the gap-fill insulating layer 7242 and may include metal such as tungsten. The barrier layer 7241 may include a pillar portion 7241A and a contact portion 7241B. The pillar portion 7241A may surround sidewalls of the gap-fill insulating layer 7242 and the contact pad 7243. The contact portion 7241B may be disposed below a lower surface of the gap-fill insulating layer 7242 and may extend in the horizontal direction to electrically connect to the gate line 7111. The insulating spacer 7141 may surround the pillar portion 7241A. The semiconductor device may include a plurality of contact plugs 7240, and each of the plurality of contact plugs 7240 may extend to a different depth and is connected to a different gate line 7111.

The semiconductor device may be manufactured using a replacement process. For example, the gate structure 7110 may be formed by forming a stack including sacrificial layers alternately stacked with the insulating layers 7112 and replacing the sacrificial layers with the gate lines 7111 through the slit. The stack may include a cell region and a contact region, and the sacrificial layers may remain in a region of the contact region spaced apart from the slit. The dielectric layers 7113 of the gate structure 7110 may be the remaining sacrificial layers. A contact hole extending through the insulating layers 7112 and the dielectric layers 7113 may be formed, and the insulating spacer 7141 may be formed on sidewalls of the stack exposed by the contact hole. By etching the dielectric layer 7113 exposed at a lower end of the insulating spacer 7141 and the contact hole, a lower end of the contact hole may be expanded in the horizontal direction to expose the gate line 7111. The contact plug 7140 or the contact plug 7240 may be formed within the insulating spacer 7141 formed in the contact hole.

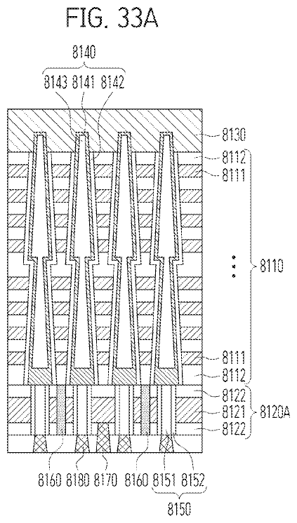

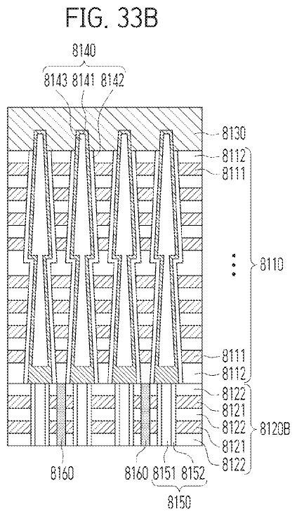

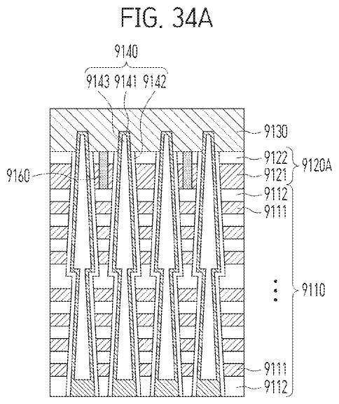

FIGS. 33A and 33B are diagrams illustrating the structure of a semiconductor device in accordance with an embodiment.

Referring to FIGS. 33A and 33B, the semiconductor device may include a first gate structure 8110, a second gate structure 8120A or 8120B, a source structure 8130, a first channel structure 8140, a second channel structure 8150, and an isolation insulating structure 8160. The first gate structure 8110 may include first gate lines 8111 alternately stacked with first insulating layers 8112. The first gate lines 8111 may be word lines or a source select line. The source structure 8130 may be disposed over the first gate structure 8110.

The second gate structure 8120A or 8120B may be disposed under the first gate structure 8110. Referring to FIG. 33A, the second gate structure 8120A may include a second gate line 8121 alternately stacked with second insulating layers 8122. The first contact plug 8170 may be connected to the second gate line 8121, and the second contact plugs 8180 may be connected to the second channel structures 8150. The first contact plug 8170 and the second contact plugs 8180 may be located in a cell region. Referring to FIG. 33B, the second gate structure 8120B may include second gate lines 8121 alternately stacked with second insulating layers 8122. Contact plugs may be connected to respective ones of the second gate lines 8121, and the contact plugs may be located in a contact region.

The second gate line 8121 may be a drain select line. The second gate line 8121 may be thicker than the first gate line 8111 or have substantially the same thickness as the first gate line 8111. The second gate line 8121 may include a different material from the first gate line 8111. For example, the first gate line 8111 may include metal such as tungsten (W) or molybdenum (Mo), and the second gate line 8121 may include polysilicon. Consecutive second gate lines 8121 disposed at the same level may be insulated by an isolation insulating structure 8160. In a plan view, the isolation insulating structures 8160 may extend in a line or a wave or zigzag shape.

The first channel structures 8140 may extend through the first gate structure 8110. The first channel structure 8140 may include a first channel layer 8141, a memory layer 8142, and/or an insulating core 8143. The second channel structures 8150 may extend through the second gate structure 8120A or 8120B and may be connected to the first channel structures 8140. The second channel structure 8150 may include a second channel layer 8151 and a gate insulating layer 8152.

The first gate structure 8110 and the second gate structure 8120A or 8120B may be formed by separate processes. For example, the first gate structure 8110 may be formed by forming a stack including sacrificial layers alternately stacked with the first insulating layers 8112 and replacing the sacrificial layers with the first gate lines 8111. The second gate structure 8120A or 8120B may be formed on the first gate structure 8110. At least one conductive layer and the second insulating layers 8122 may be formed, and the second gate lines 8121 and trenches between the second gate lines 8121 may be formed by etching at least one conductive layer and the second insulating layers 8122. The isolation insulating structures 8160 may be formed in the trenches.

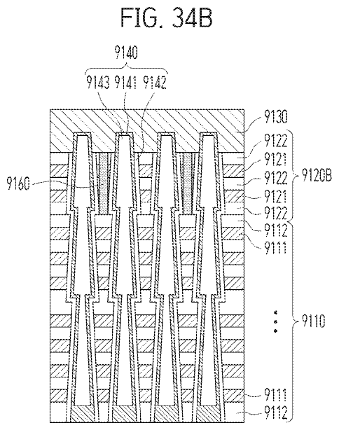

FIGS. 34A and 34B are diagrams illustrating the structure of a semiconductor device in accordance with an embodiment.

Referring to FIGS. 34A and 34B, a semiconductor device may include a first gate structure 9110, a second gate structure 9120A or 9120B, a source structure 9130, a channel structure 9140, and an isolation insulating structure 9160. The first gate structure 9110 may include first gate lines 9111 alternately stacked with first insulating layers 9112. The first gate lines 9111 may be word lines or a drain select line. The source structure 9130 may be disposed over the first gate structure 9110.

The second gate structure 9120A or 9120B may be disposed between the first gate structure 9110 and the source structure 9130. Referring to FIG. 34A, the second gate structure 9120A may include a second gate line 9121 alternately stacked with second insulating layers 9122. Referring to FIG. 34B, the second gate structure 9120B may include second gate lines 9121 alternately stacked with second insulating layers 9122. The second gate line 9121 may be a source select line. The second gate line 9121 may be thicker than the first gate line 9111 or have substantially the same thickness as the first gate line 9111. The second gate line 9121 may include a different material from the first gate line 9111. For example, the first gate line 9111 may include metal such as tungsten (W) or molybdenum (Mo), and the second gate line 9121 may include polysilicon. Consecutive second gate lines 9121 disposed at the same level may be insulated by an isolation insulating structure 9160. In a plan view, the isolation insulating structures 9160 may extend in a line or a wave or zigzag shape.

The channel structures 9140 may extend through the first gate structure 9110 and the second gate structure 9120A or 9120B. The channel structure 9140 may include a channel layer 9141, a memory layer 9142, and/or an insulating core 9143.

The first gate structure 9110 and the second gate structure 9120A or 9120B may be formed by separate processes. For example, the second gate structure 9120A or 9120B may be formed on a substrate. At least one conductive layer and the second insulating layers 9122 may be formed, and the second gate lines 9121 and trenches between the second gate lines 9121 may be formed by etching at least one conductive layer and the second insulating layers 9122. The isolation insulating structures 9160 may be formed in the trenches. The first gate structure 9110 may be formed by forming a stack including sacrificial layers alternately stacked with the first insulating layers 9112 and replacing the sacrificial layers with the first gate lines 9111. A wafer bonding process may be performed, the substrate may be removed, and the source structure 9130 may be formed. In another example, the second gate structure 9120A or 9120B including at least one conductive layer and the second insulating layers 9122 may be formed on a substrate. The first gate structure 9110 may be formed by forming a stack including sacrificial layers alternately stacked with the first insulating layers 9112 and replacing the sacrificial layers with the first gate lines 9111. A wafer bonding process may be performed, and a rear surface of the second gate structure 9120A or 9120B may be exposed by removing the substrate. The second gate lines 9121 and trenches between the second gate lines 9121 may be formed by etching at least one conductive layer and the second insulating layers 9122, and the isolation insulating structures 9160 may be formed in the trenches. The source structure 9130 may be formed.

What is claimed is:

1. A semiconductor memory device, comprising:
a stacked body including conductive layers and insulating layers that are alternately stacked;
gate patterns disposed over the stacked body;
a separation insulating pattern disposed over the stacked body, wherein the separation insulating pattern includes a first portion between adjacent gate patterns and a second portion between the gate patterns and the stacked body;
a first channel layer extending through the stacked body;
a core insulating layer disposed in the first channel layer;
a memory layer disposed between the stacked body and the first channel layer;
a second channel layer extending through the gate pattern and the second portion, wherein the second channel layer is disposed over the core insulating layer to contact the first channel layer and has a solid structure; and
a gate insulating layer disposed between the second channel layer and the gate pattern.

2. The semiconductor memory device according to claim 1, wherein the first channel layer has a ring-shaped cross-section and the second channel layer has a continuous solid cross-section in a plan view.

3. The semiconductor memory device according to claim 1, wherein the second channel layer fills a center region of the gate insulating layer.

4. The semiconductor memory device according to claim 1, further comprising:
conductive contacts contacting the second channel layers, wherein each of the conductive contacts has a greater width than each of the second channel layers.

5. The semiconductor memory device according to claim 4, wherein each of the second channel layers includes a doped area contacting the conductive contact.

6. The semiconductor memory device according to claim 1, further comprising:
a slit structure extending through the second portion and the stacked body.

7. The semiconductor memory device according to claim 6, wherein the slit structure extends between adjacent gate patterns.

8. The semiconductor memory device according to claim 1, wherein the separation insulating pattern is a single layer including the first portion and the second portion.

9. A semiconductor memory device, comprising:
a stacked body including conductive layers and insulating layers that are alternately stacked;
a separation insulating pattern disposed over the stacked body, wherein the separation insulating pattern is a single layer including a horizontal portion extending along an upper surface of the stacked body and a vertical portion protruding from the horizontal portion;
a first gate pattern on the horizontal portion of the separation insulating pattern;
a second gate pattern on the horizontal portion of the separation insulating pattern, wherein the first gate pattern and the second gate pattern are isolated from each other by the vertical portion;
a first channel structure extending through the first gate pattern, the horizontal portion, and the stacked body;
a second channel structure extending through the second gate pattern, the horizontal portion and the stacked body; and
a slit structure extending through the horizontal portion and the stacked body.

10. The semiconductor memory device according to claim 9, wherein the first channel structure comprises:
a first channel layer extending through the stacked body;
a core insulating layer disposed in the first channel layer; and
a second channel layer extending through the first gate pattern and the horizontal portion, wherein the second channel layer is disposed over the core insulating layer to contact the first channel layer and has a solid structure.

11. The semiconductor memory device according to claim 10, wherein the first channel layer has a ring-shaped cross-section and the second channel layer has a continuous solid cross-section in a plan view.

12. The semiconductor memory device according to claim 10, wherein the first channel structure further comprises:
a memory layer disposed between the stacked body and the first channel layer; and
a gate insulating layer disposed between the second channel layer and the first gate pattern.

13. The semiconductor memory device according to claim 12, wherein the second channel layer fills a center of the gate insulating layer.

14. The semiconductor memory device according to claim 9, further comprising:
conductive contact contacting the first channel structure, wherein the conductive contact has a greater width than the first channel structure.

15. The semiconductor memory device according to claim 9, further comprising:
a third gate pattern on the horizontal portion of the separation insulating pattern,
wherein the slit structure extends between the second gate pattern and the third gate pattern.

16. The semiconductor memory device according to claim 15, wherein a space between the second gate pattern and the third gate pattern has a greater width than a space between the first gate pattern and the second gate pattern.
